(19) United States
(12) Patent Application Publication
(10) Pub. No.: US 2024/0060917 A1
(43) Pub. Date: Feb. 22, 2024

(54) A METHOD OF PERFORMING QUANTITATIVE DETERMINATIONS OF NITROGEN CONTAINING UNITS

(71) Applicant: NANONORD A/S, Aalborg Ø (DK)

(72) Inventors: Ole Nørgaard JENSEN, Aalborg (DK); Niels Christian NIELSEN, Brabrand (DK); Morten Kjærulff SØRENSEN, Aarhus N (DK); Michael BEYER, Asaa (DK)

(21) Appl. No.: 18/255,504

(22) PCT Filed: Dec. 2, 2021
(86) PCT No.: PCT/DK2021/050351

§ 371 Date: Jun. 1, 2023

(30) Foreign Application Priority Data
Dec. 2, 2020 (DK) PA 2020 70811

(51) Int. Cl. G01N 24/08; G01R 33/50

(52) U.S. Cl. CPC G01N 24/08; G01R 33/50

(57) ABSTRACT

A method of generating a calibrated mathematical function for performing a quantitative determination of nitrogen containing units in a sample is described as well as a method of performing a quantitative determination of nitrogen containing units in a material and/or in a material sample. The function generation method includes generating a set of data of each of M reference samples. The set of data includes at least one N isotope NMR relaxation time and at least one isotope NMR relaxation time. Each set of reference data is associated to known quantity of nitrogen containing units of the respective reference sample. Also a processor having an embedded calibrated mathematical function and a system for performing a quantitative determination of nitrogen containing units is described.

### TECHNICAL FIELD

The invention relates to a method of and a system for determining content of nitrogen containing units, for example protein or total nitrogen in a material, such as a multi-component material e.g. comprising an organic manure slurry, a food product and/or a fermented protein slurry.

### BACKGROUND ART

Traditionally the content of nitrogen, and translation of this into constituents, such as protein, have been determined using wet chemistry-based methods such as Kjeldahl and Dumas digestion methods.

Generally, such wet chemistry-based methods are very time demanding, expensive, and relies on total nitrogen content then recalculated to protein content using assumed Jones factors (e.g. for milk the Jones factor is 6.38 gram protein per gram nitrogen).

Methods using IR instruments has also been applied, for example the Foss MilkoScan. Such IR instruments are fast, but face challenges for example for samples containing a high percentage of water. Furthermore, IR methods requires careful, regularly calibration and typically depends on data or regularly updated large databases with constituents and systems of similar type.

US 2005/0270026 discloses a method for determining the content of at least one component e.g. protein, of a sample by means of a nuclear magnetic resonance pulse spectrometer. The method comprises the steps of initially saturating the magnetization of the sample, influencing the magnetization by a sequence of radio-frequency pulses such that the signal amplitude to be observed can be determined, wherein the signal amplitudes which are determined at each time by the longitudinal and transverse relaxation time T1 and T2 and/or T2* and/or T1p, from which value for the content of the at least one component is determined, are measured at the same time in a cohesive experimental procedure. The content of the at least one component in the sample is, determined by measuring different relaxation influences. This method is rather complicated and has never been applied in practice.

### DISCLOSURE OF INVENTION

The objective of the present invention is to provide a method of performing a quantitative determination of nitrogen containing units in a selected material, which is fast, relatively simple to perform and which may be performed with a high accuracy even where the selected material is an inhomogeneous material and/or comprises a mixture of different components such as protein, water, small organic compounds, nucleic acids, carbohydrates and/or fat.

In an embodiment, an objective of the present invention is to provide a system for performing quantitative determinations of nitrogen containing units in selected materials, which system may operate very fast and with a high accuracy.

In an embodiment, an objective of the present invention is to provide a method of performing a quantitative determination of nitrogen containing units in the form of total nitrogen content which method is very accurate and at the same time may be performed relatively fast.

These and other objects have been solved by the invention or embodiments thereof as defined in the claims and as described herein below.

The method of the invention of performing a quantitative determination of nitrogen containing units in a material and/or in a material sample, comprises acquisition of at least one N isotope NMR intensity and at least one isotope NMR relaxation time of the material sample and applying the set of data in the determination.

Generally nuclear magnetic resonance (NMR) is a very complex technique and especially when the sample is a complex sample comprising multiple components, such a mixture of dissolved and undissolved components it is difficult to obtain accurate quantitative determinations. The inventors of the present invention have found that by basing the quantitative determination of set of data comprising at least one N isotope NMR intensity and at least one isotope NMR relaxation time. A very fast and surprisingly accurate quantitative determination of nitrogen containing units, such as total nitrogen content.

The method and systems of the invention, parts thereof and preferred embodiments thereof will be described further below.

It should be emphasized that the term “comprises/comprising” when used herein is to be interpreted as an open term, i.e. it should be taken to specify the presence of specifically stated feature(s), such as element(s), unit(s), integer(s), step(s), component(s) and combination(s) thereof, but does not preclude the presence or addition of one or more other stated features.

Reference made to “one embodiment” or “an embodiment” means that a particular feature, structure, or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the skilled person will understand that particular features, structures, or characteristics may be combined in any suitable manner within the scope of the invention as defined by the claims.

The term “substantially” should herein be taken to mean that ordinary product variances and tolerances are comprised.

The term nitrogen containing units is herein used to include the nitrogen containing units in dissociated and undissociated form.

The term material sample means a sample withdrawn from the material in question and optionally subjected to additional preparation prior to performing the NMR measurements.

Unless otherwise specified the determination is performed at 39° C. and at atmosphere pressure. It should be understood that the determination may be performed at any temperature and pressure where at least one nitrogen containing unit preferably is in dissociated or partly dissociated form. It is desired that the measurement performed on the material sample are performed at same temperature as the measurements performed on the reference samples. In an embodiment, the temperature of the material sample and the respective reference samples during the NMR measurements performed thereon is identical or preferably with at most 1° C. difference, preferably within at most 0.5° C. difference, such as within at most 0.2° C. difference, such as within at most 0.1° C. difference.

In an embodiment, known or measured larger differences in temperature between material sample and the respective reference samples may be handled through consideration in the mathematical model relating measurements to quantitative determination of nitrogen containing units.

The method of performing a quantitative determination of nitrogen containing units in a material sample comprises
providing the material sample of a material
acquiring a set of material sample data comprising at least one N isotope NMR intensity and at least one isotope NMR relaxation time of said material sample;
processing the set of material sample data according to a calibrated mathematical function and
determining the quantity of nitrogen containing units in said material sample and/or in said material.

The term “material sample data” is used to denote that the denoted data is for the material sample. In the same way the term “of reference data” is used to denote that the denoted date is for the reference sample in question.

Thanks to the inventors of the present invention, a new and very effective method and system for nitrogen determination has been provided. The inventors have found that there is a correlation between sets of data comprising N isotope NMR intensity and isotope NMR relaxation times relative to the nitrogen containing units. Thus, a calibrated mathematical function representing the correlation between such sets of data and their respective known quantity of nitrogen containing units may be determined and applied in the quantitative determination of nitrogen containing units in a material and/or a material sample.

The invention also comprises a method of generating a calibrated mathematical function for performing the quantitative determination of nitrogen containing units in a sample, such as a material sample as defined herein.

The method of generating a calibrated mathematical function for performing the quantitative determination of nitrogen containing units in a sample is also referred to as “the function generation method”.

In the same way the method of performing a quantitative determination of nitrogen containing units in a material sample is referred to as “the nitrogen determination method”.

The function generation method comprises
providing a number M of reference samples with different and known quantity of nitrogen containing units, wherein the number M is at least 2;
for each of the reference samples acquiring a set of reference data comprising at least one N isotope NMR intensity and at least one isotope NMR relaxation time and wherein each set of reference data is associated to the respective known quantity of nitrogen containing units; and
processing the sets of reference data for the M reference samples and their respective associated known quantity of nitrogen containing units to generate the calibrated mathematical function,
   wherein M is an integer.

The respective sets of reference data may comprise additional data, such as data representing a time attribute, an identification attribute, a temperature contribute, a magnetic field attribute and/or data representing any other information of the reference sample in question or the condition for the NMR measurements. In addition further isotope NMR intensity data may be included, such as proton isotope NMR intensity data.

In the same way the set of material sample data may comprise additional data such as data representing a time attribute, an identification attribute, a temperature contribute, a magnetic field attribute and/or data representing any other information of the material sample in question or the condition for the NMR measurements as well as further isotope NMR intensity data may be included, such as proton isotope NMR intensity data.

The quantitative determination may be a concentration determination, a weight determination a relative amount determination or any other quantitative determination, such as the total nitrogen content, e.g. in ppm. In the same way the known quantity of nitrogen containing units is provided in the same quantity indication.

In the function generation method the number M of reference samples is at least two. An additional zero point data set may be applied as well including a background data set representing a nitrogen free reference sample.

Advantageously, the at least 5, such as at least 20, such as at least 50, such as at least 100, such as at least 20, such 1000 or more. In principle the higher the number M of reference samples, the more accurate will the quantitative determination of nitrogen containing units, using the generated calibrated mathematical function, be. However, for most determination it may be sufficient using a lower number of M of reference samples.

In an embodiment, the function generation method comprises reprocessing the sets of reference data for the M reference samples and their respective associated known quantity of nitrogen containing units together with one or more sets of material sample sets of data and their respective determined quantity of nitrogen containing units to updating the calibrated mathematical function.

The nitrogen containing units may be nitrogen atoms (i.e. total nitrogen is determined) or any component, or group of components, such as one or more nitrogen containing molecules, such as protein, amino acids, amines, amides, nucleic acids, urea, ammonium, nitrate, nitrite or combinations thereof.

Thus, the calibrated mathematical function may for example in an embodiment, be generated for determinations where the nitrogen containing units are proteins. Thus, in this embodiment the known quantity of nitrogen containing units for the respective reference samples are known quantities of protein.

In another embodiment, the calibrated mathematical function is generated for determinations where the nitrogen containing units are the total quantity of nitrogen atoms. Thus, in this embodiment the known quantity of nitrogen containing units for the respective reference samples are known quantities of nitrogen atoms.

In a further embodiment, the calibrated mathematical function is generated for determinations where the nitrogen containing units are species like urea, ammonia, nitrate, nitrite or amino acids. Thus, in this embodiment the known quantity of nitrogen containing units for the respective reference samples are known quantities of respectively urea, ammonia, nitrate, nitrite or amino acids.

In a further embodiment, the calibrated mathematical function is generated for determinations where the nitrogen containing units are the quantity of nitrogen atoms associated to or bound in compounds, such as nitrogen atoms associated to or bound in digestable protein, wherein the preparation of the reference samples and the material sample is subjected to an enzymatic degradation. Thus, in this embodiment the known quantity of nitrogen containing units for the respective reference samples are known quantities of nitrogen atoms in the digestable protein of the sample. The determination of quantities of nitrogen atoms may be a determination of total nitrogen content or it may offer the potential to discriminate the total nitrogen content into specific nitrogen containing species, such as organic nitrogen, ammonia, nitrate, or nitrite.

In an embodiment, the quantitative determination is by weight. Advantageously, the quantitative determination is by weight where the nitrogen containing units are proteins.

In an embodiment, the quantitative determination is by number. In an embodiment, the quantitative determination is by number where the nitrogen containing units are nitrogen atoms—i.e. total nitrogen determination, e.g. determined in ppm.

In an embodiment, the quantitative determination is by weight where the nitrogen containing units is nitrogen atoms.

For material samples where it is expected that most of the nitrogen is protein bound nitrogen—e.g. food products, the protein content may be determined from the total nitrogen determination using the Jones factor.

The at least one isotope NMR relaxation time comprises at least one relaxation time for at least one of the isotopes ¹H, ²H, ⁶Li, ⁷Li, ¹⁰B, ¹¹B, ¹⁴N, ¹⁵N, ²³Na, ³¹P, ³⁹K, ⁸⁵Rb, ⁸⁷Rb, ¹³³Cs, ²⁵Mg, ¹⁹F, ³⁵Cl, ³⁷Cl, ⁵¹V, ⁷⁹Br, ⁸¹Br, ¹²⁷I, ¹⁷O, or ¹³C.

In an embodiment, the isotope NMR relaxation time comprises at least one relaxation time for another isotope than ¹⁴N and ¹⁵N.

Naturally the isotope for which the relaxation time is measured should naturally be an isotope that is expected to be and advantageously is present in the reference samples and/or material sample in question.

In an embodiment, an additive comprising the isotope for which the isotope NMR relaxation time is determined may be added to the respective samples. The additive may for example be a salt, such a sodium chloride or a phosphorus salt. The amount of additive added to the material sample is advantageously similar, such as preferably within ±10% of the amount of the same additive added to the respective reference samples. In an embodiment, the additive is added to the material sample and to the respective reference samples in amounts which differs less than 5%, such as in amounts that differs less than 2%, such as in identical amounts.

In an embodiment, the at least one isotope NMR relaxation time comprises at least one relaxation time for at least one of the isotopes ¹H, ²³Na, ³¹p, ¹⁹F, ³⁵Cl, or ³⁷Cl.

In an embodiment, the at least one isotope NMR relaxation time comprises at least one relaxation time for at least one of the isotopes ¹⁴N or ¹⁵N.

In an embodiment, the at least one isotope NMR relaxation time does not include any relaxation time for the isotopes ¹⁴N and/or ¹⁵N.

In an embodiment, the at least one isotope NMR relaxation time comprises at least one relaxation time for at least one halogen isotope.

In an embodiment, the at least one isotope NMR relaxation time comprises at least one relaxation time for at least one oxygen and/or carbon isotope.

Advantageously, the at least one isotope NMR relaxation time comprises at least one proton NMR relaxation time.

It has been found that the most accurate determinations are obtained where the reference samples and/or material sample comprise at least a portion of the nitrogen containing units in dissociated form.

Advantageously, the reference samples and/or the material sample during the NMR measurements are liquid containing samples, comprising at least a portion of the nitrogen containing units in dissociated form.

In an embodiment, the reference samples and/or the material sample during the NMR measurements comprise at least one solvent, such as an organic or an inorganic solvent. Examples of solvents include one or more of the solvents water; ammonia; alcohols, such as methanol, ethanol or butanol; acetic acid; hydrochloric acid; sulfuric acid; sodium hydroxide; hexane, toluene, dimethyl sulfoxide (DMSO) and any combinations comprising one or more of these.

In addition, the reference samples and or the material sample may comprise a surfactant, a detergent, an enzyme, a degrading substance or any combinations comprising at least one of these. In addition the reference samples may comprise acid or base.

The surfactant may serve the purpose of increasing dispersing of solid portions of the sample. The surfactant may be any type of surfactant. The detergent may advantageously comprise an amphiphilic component: partly hydrophilic (polar) and partly hydrophobic (non-polar).

The provision of the reference samples may comprise preparation of the reference samples from one or more precursor materials. For example, the respective reference samples may be prepared from respective precursor reference samples.

The known quantity of nitrogen containing units for the reference samples may be the actual quantity of the nitrogen containing units or it may be a relative quantity of the nitrogen containing units e.g. in the form of the actual quantity prior to one or more steps of preparation—such as the actual quality of the precursor reference samples, wherein the sample material is subjected to the same or corresponding one or more steps of preparation. Thereby the quantitative determination of nitrogen containing units are the determination of the content in the material sample prior the one or more steps of preparation, such as for example of the material.

The reference samples and or the material sample may advantageously comprise biological samples, such as one or more of food product and manure.

The food product may for example comprise livestock feed product, such as product comprising grains (e.g. Rye, Wheat, Oat and Barley), soybean meal, feed peas and/or feed corn.

The manure, may for example comprise liquid manure and/or animal slurry

The reference samples and or the material sample may in an embodiment comprise complex mixtures such as waste streams or waste water.

In an embodiment, the preparation of the reference samples comprises at least one of
comminuting the at least one precursor material;
adding at least one solvent to the at least one precursor material;
adding a surfactant, a detergent and/or buffer to the at least one precursor material; and/or
subjecting the at least one precursor material to degradation, such as enzymatic digestion and/or chemical and/or thermal degradation.

The at least one precursor material to degradation may in an embodiment comprise subjecting the precursor material to irradiation.

It is desired that the material sample as withdrawn from the material is subjected to the same or corresponding preparation as the preparation of the reference samples used for generating calibrated mathematical function. Thereby a stage of comminuting, digesting, dispersing and dissolving is equivalent and the amount of dissociated nitrogen containing units, such as dissolved protein for a given nitrogen containing unit concentration may be practically identical.

The preparation of the material sample and preferably the reference samples depends largely on the material selected (also referred to as the selected material) for the determination and whether or not it is in liquid form itself.

Liquid sample means herein any liquid containing material comprising free liquid. Advantageously, at least about 50% by weight is in liquid form, such as at least about 60%, such as at least about 70%, such as at least about 80%, such as at least about 90% by volume is in liquid form. In an embodiment, the liquid sample is free of solid material.

The selected material may in principle be any kind of material suspected of containing nitrogen containing units, such as ammonium and/or protein. If the selected material is solid, a sufficient amount of solvent is advantageously added and the sample may be comminuted e.g. using a blender or other means, such as a pressure device or by subjecting the sample to heating, freezing, microwaves or infrared irradiation or similar.

If the selected material is a liquid with solid parts, the solid parts may optionally be comminuted.

In an embodiment, the preparation of the sample comprises withdrawing material sample from the material and ad subjecting it to one or more steps of preparation.

The solubility of for example protein may e.g. be increased by adjusting the pH value of the sample and/or by adding salts, such as NaCl, Na₂SO₄ or (NH₄)₂SO₄, or by adding a detergent, such as sodium dodecyl sulfate (SDS). In an embodiment, the solubility may be increased by adding a surfactant.

The material sample may be shacked, stirred or blended for a desired time to ensure a good solubility. In addition, the preparation of the material sample, may be comprise heating the material sample to increase solubility of nitrogen containing units, for example heating the material sample to a temperature above 30° C., but less than coagulation temperature, such as to a temperature of from about 40° C. to about 50° C.

In an embodiment, the preparation of the material sample comprises adjusting the pH value, preferably by adding a buffer, adding an acid and/or adding a base. The prepared material sample may in an embodiment have a pH value between 6 and 9, such as between 7 and 9, such as about 8.

In an embodiment, where the nitrogen containing units comprises ammonia, the prepared material sample may have a pH value less than 7, such as 2-6, e.g. where the sample is fermented.

In an embodiment, the preparation of the material sample comprises digestion the material sample enzymatic digestion or by chemical hydrolysis, optionally catalyzed by acidic or alkaline conditions. After the digestion the pH value may be adjusted if desired.

The digestion of nitrogen containing units, such as protein is in particular desired where the selected material comprises large proteins, such as about 40.000 Dalton or larger or large quantities of other macromolecular species, such as carbohydrates. The protein digestion may increase the solubility or accessibility of the proteins.

Where the selected material comprises protein complex(es), the preparation of the material sample may advantageously comprise extracting proteins from the one or more protein complexes. This extraction may preferably comprise adding a detergent and/or buffer solution, such as sodium dodecyl sulfate (SDS) and/or Triton-X.

Alternatively or in addition the extraction may comprise a heat treatment and/or pressure treatment, such as a pulsed pressure treatment. The samples may also in an embodiment be stabilized by irradiation, such as gamma irradiation.

The protein complex may e.g. comprise two or more associated polypeptide chains linked by non-covalent protein-protein interactions. The protein complex may for example have a quaternary structure, such as hemoglobin.

Where the selected material comprises cell bound nitrogen containing units, and the preparation may comprise subjecting the cells to cell lysis.

Where the selected material comprises the nitrogen containing units in the form of proteins, carbohydrates or nucleic acid matrices, the preparation may comprise treatment with heat, acid, pressure and/or mechanical matrix disruption.

In an embodiment, the preparation of the material sample comprises denaturation of optional proteins using detergent, such as sodium dodecyl sulfate (SDS) and/or chelating agents such as Ethylenediaminetetraacetic acid (EDTA). The detergent may ensure that at least a part of the protein remains dissolved. In an embodiment, the method comprises adding urea to increase solubility.

The function generation method advantageously comprises determining the at least one N isotope NMR intensity of each of the reference samples comprising
subjecting the reference sample to a first series of nuclear magnetic resonance (NMR) pulse sequence in a first magnetic field, wherein the first series of nuclear magnetic resonance (NMR) pulse sequence comprising a frequency corresponding to a N isotope NMR frequency in the first magnetic field;
receiving a first plurality of NMR measurement signals from the reference sample responsive to the applied N isotope NMR frequency; and
determining the at least one N isotope NMR intensity from the first plurality of NMR measurement signals.

The first magnetic field is advantageously a static magnetic field, such as a low field of from about 0.1 to about 5 tesla. It has been found to be very beneficial using a low-field NMR spectrometer. Such low-field NMR spectrometer may be both less costly and smaller than larger field NMR spectrometer. Low field MNR spectrometers is herein used to mean an NMR spectrometer with a maximal magnetic field about 5 Tesla, preferably about 3 Tesla or les, such as about 3 tesla or less.

The NMR spectrometer may advantageously be a movable NMR spectrometer, such as an NMR spectrometer carried on wheels.

The at least one N isotope NMR intensity may at least one of a ¹⁴N isotope NMR intensity and a ¹⁵N isotope NMR intensity. Preferably the N isotope NMR intensity comprises ¹⁴N isotope NMR intensity.

In addition the function generating method may comprise determining one or more additional isotope NMR intensities. In an embodiment, the method comprises determining isotope NMR intensity for at least one of the isotopes ¹H, ²³Na, ³¹P, ¹⁹F, ³⁵Cl, or ³⁷Cl. In an embodiment, the method comprises determining proton isotope NMR intensity of the respective samples.

The function generation method may thus comprise determining isotope NMR intensities for nuclei different from N comprising
subjecting the reference sample to a third series of nuclear magnetic resonance (NMR) pulse sequence in a third magnetic field comprising a frequency corresponding to an isotope NMR frequency in the third magnetic field;
receiving a third plurality of NMR measurement signals from the reference sample responsive to the applied isotope NMR frequency; and
determining the at least one isotope NMR intensity from the third plurality of NMR measurement signals, wherein the isotope is different from isotopes of the N nuclei.

The function generation method advantageously comprises determining the at least one isotope NMR relaxation time comprising
subjecting the reference sample to a second series of nuclear magnetic resonance (NMR) pulse sequence in a second magnetic field comprising a frequency corresponding to an isotope NMR frequency in the second magnetic field;
receiving a second plurality of NMR measurement signals from the reference sample responsive to the applied isotope NMR frequency; and
determining the at least one isotope NMR relaxation time from the second plurality of NMR measurement signals.

The second magnetic field is advantageously a static magnetic field and it may be equal to or different from the first magnetic field. Generally, it is desired that the first and the second magnetic field is identical. Thereby the N isotope NMR intensity measurement(s) and the isotope NMR relaxation time(s) may be performed very fast e.g. immediately after each other.

The at least one isotope NMR relaxation time advantageously comprises at least one of the relaxation times a spin-lattice relaxation time (T1) or a spin-spin relaxation time (T2). In an embodiment, the at least one isotope NMR relaxation time advantageously comprises the relaxation time T1 rho also known as T1ρ or “spin lock” T1. The “rho” in the sequence name refers to a “ro”tating frame and the sequence has elements of both T1 and T2 weighting. After the initial 90° RF pulse, tipping the magnetization vector into the transverse plane, a second pulse is applied parallel to the tipped magnetization vector. This effectively locks the magnetization vector into the transverse plane (“ro”tating frame) without phase decay (as with T2 decay). The decay of this locked magnetization to 0 is the T1 rho time.

Nuclear magnetic resonance—abbreviated NMR—is well known and is a phenomenon, which occurs when the nuclei of an isotope with a nuclear spin in a magnetic field absorb and re-emit electromagnetic radiation. The emitted electromagnetic radiation has a specific resonance frequency, which depends on the strength of the magnetic field and the magnetic properties of the isotope. NMR allows the observation of specific quantum mechanical magnetic properties of the atomic nucleus. Many scientific techniques exploit NMR phenomena to study molecular physics, crystals, and non-crystalline materials through NMR spectroscopy. NMR is also routinely used in advanced medical imaging techniques, such as in magnetic resonance imaging (MRI).

The terms “spectroscope” and “spectrometer” are used interchangeable and in the same way a spectroscope is the same as a spectrometer.

NMR spectroscopy is well known in the art and has for many years been applied for laboratory measurements in particular where other measurement methods could not be used. NMR spectroscopy is performed using an NMR spectrometer. Examples of spectrometers are e.g. described in U.S. Pat. No. 6,310,480 and in U.S. Pat. No. 5,023,551. The term NMR spectrometer also includes an NMR relaxometer.

General background of NMR formation evaluation can be found, for example in U.S. Pat. No. 5,023,551.

A general background description of NMR measurement can be found in “Understanding NMR Spectroscopy” by James Keeler, John Wiley & Sons Ltd, 2005 or in a practically oriented setting in, e.g., “NMR Logging Principles and Applications” by George R. Coates et al, Halliburton Energy Services, 1999. See in particular chapter 4.

The terms ‘NMR reading’ and “NMR measurement” are used interchangeable. It should be observed that used in singular for also includes the plural form i.e. a plurality of NMR readings unless other is specified. Often many NMR readings are performed and an average of the readings is used for the further analysis.

The term “relaxation” describes processes by which nuclear magnetization excited to a non-equilibrium state return to the equilibrium state. In other words, relaxation describes how fast spins “forget” the direction in which they are oriented. Methods of measuring relaxation times T1 and T2 are well known in the art. The same applies to rotating frame relaxation times, such as T1ρ.

The relaxation time T2 is herein used to include “apparent T2” (sometimes also called T2*). Apparent T2 includes a contribution caused by instrumental effects, such as magnetic field inhomogeneity. Instrumental effects (e.g. large magnet inhomogeneity) may cause that measured T2 relaxation times reflect apparent T2 relaxation times rather than pure natural T2 relaxation times. However, such instrumental effects may for example be minimized using a proper echo-train pulse sequence (e.g. CPMG) and may often be ignored (at least for the intensity determination), specifically where the same instrument is used for generating the standard curve and for performing the measurement.

The NMR spectrometer advantageously comprises an integrated or an external computer associated with a memory.

T2 relaxation is also called the transverse relaxation. Generally, T2 relaxation is a complex phenomenon and involves decoherence of transverse nuclear spin magnetization. T2 relaxation values are substantially not dependent on the magnetic field applied or the NMR frequency applied during excitation of the ¹H nuclei. Hence, it is preferred that the generated data comprises T2-dependent time-domain data. When using T1-dependent time-domain data, it is preferred that the magnetic field applied and/or the NMR frequency applied for generating the standard curve is the same or within +/−20% from the magnetic field applied and/or the NMR frequency applied when performing the quantitative nitrogen containing unit determination.

A standard technique for measuring NMR signals and obtaining information about the spin-spin relaxation time T2 utilizing CPMG (Carr-Purcell-Meiboom-Gill) sequence is as follows. As is well known after a wait time that precedes each pulse sequence, a 90-degree exciting pulse is emitted by an RF antenna, which causes the spins to start processing in the transverse plane perpendicular to the external magnetic field. After a delay, a first 180-degree pulse is emitted by the RF antenna. The first 180-degree pulse causes the spins, which are dephasing in the transverse plane, to reverse direction and to refocus and subsequently cause an initial spin echo to appear. A second 180-degree refocusing pulse can be emitted by the RF antenna, which subsequently causes a second spin echo to appear. Thereafter, the RF antenna emits a series of 180-degree pulses separated by a short time delay. This series of 180-degree pulses repeatedly reverse the spins, causing a series of “spin echoes” to appear. The train of spin echoes is measured and processed to determine the spin-spin relaxation time T2.

In an embodiment, the refocusing RF pulse(s) is/are applied after the exciting RF pulse with an echo-delay time-period between the exciting RF pulse and the subsequent refocusing RF pulse. In the case of multiple echoes, the refocusing RF pulses are typically separated by twice the delay from the exciting RF pulse to the first refocusing RF pulse. The echo-delay time (also called echo time TE) is preferably of about 500 μs or less, more preferably about 150 μs or less, such as in the range from about 50 μs to about 100 μs depending on the homogeneity of the magnetic field applied (here assuming an inhomogeneity of the applied magnetic field of about 500 ppm, while longer an echo-delay time is suitable if a more homogenous magnetic field is applied).

This method is generally called the “spin echo” method and was first described by Erwin Hahn in 1950. Further information can be found in Hahn, E. L. (1950). “Spin echoes”. Physical Review 80: 580-594, which is hereby incorporated by reference.

A typical echo-delay time is from about 10 μs to about 50 ms, preferably from about 50 μs to about 200 μs. The repeat delay time (also called wait time TW) is the time between the last CPMG 180° pulse and the first CPMG pulse of the next experiment at the same frequency. This time is the time during which magnetic polarization or T1 recovery takes place. It is also known as polarization time. The repeat delay time, typically in the order of 10 ms to 10 s, should typically be sufficiently long to ensure full recovery of the polarization, but may also be shortened to obtain T1-dependent data.

An alternative or additional recording of rotating frame T1-dependent data (called T1ρ) may be obtained by spin locking the polarization by using RF irradiation.

This basic spin echo method provides good results for obtaining T1-modulated data and T2-modulated data by varying the echo-delay time or by using plurality of refocusing pulses.

The delay between refocusing pulses is also called the Echo Spacing and indicates the time identical to the time between adjacent echoes. In a CPMG sequence, the TE also reflects the time between 180° pulses.

The data representing signal dependence on T2 (T2-dependent data) may advantageously be acquired using a spin echo train experiment (e.g. the CPMG pulse sequence) or a series of spin echo experiments. The acquisition of T1 information may advantageously comprise one or more acquisitions with the saturation recovery or inversion recovery, or modified experiment versions based on these experiments.

This CPMG method is an improvement of the spin echo method by Hahn. This method was provided by Carr and Purcell and provides an improved determination of the T2 relaxation values, which again allows for better quantitative determination of the signal intensity via more precise consideration of T2 effects obtained from single or multi curve fitting for most precise envelope of spin echo amplitudes.

Further information about the Carr and Purcell method (which is a basic echo-train method and the fundament for the CPMG method) can be found in Carr, H. Y.; Purcell, E. M. (1954). “Effects of Diffusion on Free Precession in Nuclear Magnetic Resonance Experiments”. Physical Review 94: 630-638, which is hereby incorporated by reference.

Further information about the application of CPMG methods to quadrupolar spin nuclei can be found in Larsen, F. H.; Jakobsen, H. J.; Ellis, P. D.; Nielsen, N.C. (1997). “Sensitivity-Enhanced Quadrupolar-Echo NMR of Half-Integer Quadrupolar Nuclei. Magnitudes and Relative Orientation of Chemical Shielding and Quadrupolar Coupling Tensors”. Journal of Physical Chemistry A, 101, 8597-8606.

In an embodiment of the function generation method, the step of processing the sets of reference data for the M reference samples and their respective associated known quantity of nitrogen containing units to generate the calibrated mathematical function comprises performing a regression analysis to determine the calibrated mathematical function as a best fit formula for the relationship between the respective sets of reference data and their associated known quantity of nitrogen containing units.

Models for performing regression analysis are well known. The regression analysis may be performed on the two or more variable data of the respective reference data sets and their dependent quantity data representing the known quantity of nitrogen containing units. The data are fitted by a method of successive approximations until a desired accurate calibrated mathematical function has been generated.

The regression analysis may be linear, but will most often be a non-linear regression analysis.

In an embodiment of the function generation method, the step of processing the sets of reference data for the M reference samples and their respective associated known quantity of nitrogen containing units to generate the calibrated mathematical function comprises processing the respective sets of reference data and their associated known quantity of nitrogen containing units in a data processor. The data processor may in an embodiment be programmed for performing the regression analysis for generating the calibrated mathematical function.

In an embodiment, the calibrated mathematical function is generated by processing the respective sets of reference data and their associated known quantity of nitrogen containing units according to the mathematical expression, such as:

TN(Known)=k₁+Int(14N)[k₂+k₃1/T2(1H)+k₄(1/T2(1H))²+k₅1/T1(1H)+k₆(1/T1(1H))²],

wherein the method comprises determining the coefficients k₁-k₆ by calibrating through a best-fit match for the respective sets of reference data and their associated known quantity of total nitrogen content.

The contribution by the k5 and k6 part of the mathematical function may often be relatively small and for simplification these parts may be replaced by a constant ki or simply set to zero (e.g. ki=0).

The mathematical expression may then be

TN(Known)=k₁+Int(14N)[k₂+k₃1/T2(1H)+k₄(1/T2(1H))²+kᵢ],

TN(Known)=k₁+Int(14N)[k₂+k₃1/T2(1H)+k₄(1/T2(1H))²+k₅1/T1(1H)+kᵢ],

or
wherein the method comprises determining the coefficients k₁-k₄+kᵢ or k₁-k₅+kᵢ respectively by calibrating through a best-fit match for the respective sets of reference data and their associated known quantity of total nitrogen content. As mentioned ki may alternatively be set to be zero.

In an embodiment, the calibrated mathematical function is generated by processing the respective sets of reference data and their associated known quantity of nitrogen containing units according to the mathematical expression:

TN(known)=a(int(¹⁴N))+b(1/T2(X))+c(1/T1(X))+d

wherein X is an isotope (such as 1H) and the method comprises determining the coefficients or sub-functions a-d by calibrating through a best-fit match for the respective sets of reference data and their associated known quantity of total nitrogen content. The sub-functions may be polynomials, or other types of mathematical functions.

In an embodiment, the calibrated mathematical function is generated by processing the respective sets of reference data and their associated known quantity of nitrogen containing units according to the mathematical expression:

TN(known)=a(int(¹⁴N))+b(1/T2(¹H))+c,

wherein the method comprises determining the coefficients a, b and c by calibrating through a best-fit match for the respective sets of reference data and their associated known quantity of total nitrogen content.

In an embodiment, the data processor may be configured for generating the calibrated mathematical function using artificial intelligence. The term “artificial intelligence” is herein used to mean that the processor is not fully preprogrammed for generating the calibrated mathematical function and that the processor is learning the relationship between the between the respective sets of reference data and their associated known quantity of nitrogen containing units to generate the calibrated mathematical function as an embedded learned knowledge.

In an embodiment, the calibrated mathematical function is generated by machine learning, such as deep learning by processing the sets of reference data for the M reference samples and their respective associated known quantity of nitrogen containing units in a data processor.

The data processor may advantageously be trained by being subjected to supervised learning using the respective sets of reference data and their associated known quantity of nitrogen containing units. Thereby a highly accurate calibrated mathematical function may be generated even where the number of reference samples and thereby reference sets of data with associated known quantity of nitrogen containing units is relatively low.

In an embodiment, the data processor is trained by unsupervised learning using the respective sets of reference data and their associated known quantity of nitrogen containing units. Training the processor by unsupervised learning may require a higher number of reference sets of data with associated known quantity of nitrogen containing units than when training by supervised learning. The resulting generated calibrated mathematical function may be of a very high accuracy.

The processor may advantageously comprise a neural network, such as a neural network comprising a plurality of layers of nodes (also called neurons), preferably including two or more hidden layers.

The nitrogen determination method comprises
providing the material sample of the material
acquiring a set of material sample data comprising at least one N isotope NMR intensity and at least one isotope NMR relaxation time of the material sample;
processing the set of material sample data according to a calibrated mathematical function and
determining the quantity of nitrogen containing units in the material sample and/or in the material.

Advantageously, the calibrated mathematical function is obtainable by a method comprising generating a plurality of data sets of at least one N isotope NMR intensity and at least one isotope NMR relaxation time for reference samples with known quantity of nitrogen containing units and performing a regression analysis e.g. such as described above.

The calibrated mathematical function preferably has the form

TN(determined)=k₁+Int(14N)[k₂+k₃1/T2(1H)+k₄(1/T2(1H))²+k₅1/T1(1H)+k₆(1/T1(1H))²],

wherein the coefficients k₁-k₆ have been determined as described above.

The calibrated mathematical function may conveniently have the form

TN(determined)=k₁+Int(14N)[k₂+k₃1/T2(1H)+k₄(1/T2(1H))²+kᵢ],

wherein the coefficients k₁-k₄ and kᵢ have been determined as described above.

The calibrated mathematical function may conveniently have the form

TN(determined)=k₁+Int(14N)[k₂+k₃1/T2(1H)+k₄(1/T2(1H))²+k₅1/T1(1H)+kᵢ],

wherein the coefficients k₁-k₅ and ki have been determined as described above.

The calibrated mathematical function may conveniently have the form

TN(determined)=a(int(¹⁴N))+b(1/T2(1H))+c,

wherein the coefficients a, b and c have been determined as described above.

The calibrated mathematical function may conveniently have the form

TN(determined)=a(int(¹⁴N))+b(1/T2(X))+c(1/T1(X))+d,

wherein X is an isotope (such as 1H) and wherein the coefficients or sub-functions a-d have been determined as described above.

The reference samples applied for the function generation method are advantageously of same type than the material sample. The term “type” is herein used to mean that they are qualitatively similar in respect to one or more of the molecules they contain. Examples of types of samples include manure suspension sample type, fertilizer sample type, livestock feed sample type, milk sample type, cheese sample type, meat sample type and mixtures thereof such as lasagna sample type, protein supplement/drink sample type etc. Other examples may be waste streams or waste water.

Advantageously, the nitrogen containing units determined in the material sample and/or in the material corresponds to or is qualitatively identical to the nitrogen containing units determined in the reference samples for generating the calibrated mathematical function.

The nitrogen containing units determined in the material sample or the material may advantageously correspond to or be identical to the nitrogen containing units for which the known quantity for the respective reference samples are applied in the function generation method, such as nitrogen atoms and/or proteins.

In an embodiment, the nitrogen containing units determined in the material sample and/or in the material are nitrogen containing molecules, preferably to thereby determining the total nitrogen content.

The quantitative determination may by weight and/or by number and may optionally be converted between weight, number, concentration etc. Such conversion may e.g. be performed by the processor.

The at least one isotope NMR relaxation time comprises at least one relaxation time for at least one of the isotopes ¹H, ²H, ⁶Li, ⁷Li, ¹⁰B, ¹¹B, ¹⁴N, ¹⁵N, ²³Na, ³¹P, ³⁹K, ⁸⁵Rb, ⁸⁷Rb, ¹³³Cs, ²⁵Mg, ¹⁹F, ³⁵Cl, ³⁷Cl, ⁵¹V, ⁷⁹Br, ⁸¹Br, ¹²⁷I, ¹⁷O, or ¹³C. Preferably the at least one isotope NMR relaxation time determined for the material sample comprises at least one of the at least one isotope NMR relaxation time determined in the reference samples for generating the calibrated mathematical function.

In an embodiment, the isotope NMR relaxation time comprises at least one relaxation time for another isotope than ¹⁴N and ¹⁵N.

In an embodiment, the at least one isotope NMR relaxation time does not include any relaxation time for the isotopes ¹⁴N and/or ¹⁵N.

In an embodiment, the one or more isotope NMR relaxation time(s) in the nitrogen determination method is/are of the same isotope(s) as the one or more isotope NMR relaxation time(s) applied in the function generation method. In particular it is preferred that the one or more isotope NMR relaxation time(s) includes at least one proton NMR relaxation time.

Advantageously, the material sample during the NMR measurements comprises liquid, wherein at least a portion of the nitrogen containing units in dissociated form.

The material sample may conveniently comprises at least one solvent during the NMR measurements, such as an organic or an inorganic solvents e.g. the solvents mentioned above.

In an embodiment material sample comprises a surfactant, a detergent, an enzyme, a degrading substance or any combinations comprising at least one of these.

The material sample may be a sample withdrawn from the material without further preparation or it may be withdrawn from the material and subjected to further preparation.

In an embodiment, the reference samples and the material samples is subjected to the same one or more preparation steps. In this embodiment the known quantities of nitrogen containing units applied in the function generation method, may be the quantity prior to the preparation or after the preparation. Hence, the nitrogen determination method med result in a direct determination of the nitrogen containing units in the material sample prior to or without pretreatment and hence, the nitrogen containing units in the material.

In an embodiment, where the determination of the nitrogen containing units in the material sample is after its pretreatment, the nitrogen containing units of the material may be calculated taking the pretreatment into consideration.

In an embodiment, provision of the material sample comprises withdrawing a portion from the material and subjecting it to additional preparation comprising at least one of
comminuting the at least one precursor material;
adding at least one solvent to the at least one precursor material;
adding a surfactant, a detergent and/or buffer to the at least one precursor material; and/or
subjecting the at least one precursor material to degradation, such as enzymatic digestion and/or chemical and/or thermal degradation.

As mentioned, the withdrawn portion may advantageously be prepared by the same method as preparation of the reference samples.

The acquisition of the set of material sample data comprises determining the at least one N isotope NMR intensity advantageously comprises
subjecting the material sample to a first series of nuclear magnetic resonance (NMR) pulse sequence in the first magnetic field, wherein the first series of nuclear magnetic resonance (NMR) pulse sequence comprising a frequency corresponding to a N isotope NMR frequency in the first magnetic field;
receiving a first plurality of NMR measurement signals from the material sample responsive to the applied N isotope NMR frequency; and
determining the at least one N isotope NMR intensity from the first plurality of NMR measurement signals.

The at least one N isotope NMR intensity preferably comprises least one of a ¹⁴N isotope NMR intensity and a ¹⁵N isotope NMR intensity and preferably the same as applied on the function generation method.

In addition the acquisition of the set of material sample data may comprise determining one or more additional isotope NMR intensities, such as determining isotope NMR intensity for at least one of the isotopes ¹H, ²³Na, ³¹P, ¹⁹F, ³⁵Cl, or ³⁷Cl. In an embodiment, the method comprises determining proton isotope NMR intensity of the respective samples.

The acquisition of the set of material sample data may thus comprise determining isotope NMR intensities for nuclei different from N
subjecting the reference sample to a third series of nuclear magnetic resonance (NMR) pulse sequence in a third magnetic field comprising a frequency corresponding to an isotope NMR frequency in the third magnetic field;
receiving a third plurality of NMR measurement signals from the reference sample responsive to the applied isotope NMR frequency; and
determining the at least one isotope NMR intensity from the third plurality of NMR measurement signals, wherein the isotope is different from isotopes of the N nuclei.

The acquisition of the set of material sample data comprises determining the at least one isotope NMR relaxation time advantageously comprising
subjecting the material sample to a second series of nuclear magnetic resonance (NMR) pulse sequence in the second magnetic field comprising a frequency corresponding to an isotope NMR frequency in the second magnetic field;
receiving a second plurality of NMR measurement signals from the material sample responsive to the applied isotope NMR frequency; and
determining the at least one isotope NMR relaxation time from the second plurality of NMR measurement signals.

The first and the second magnetic field may advantageously be as applied in the function generation method.

In an embodiment, the first and the second magnetic field(s) applied in the nitrogen determination method is/are the identical or within +/−10%, such as within +/−5%, such as within +/−1%, from the first and the second magnetic field(s) applied in the function generation method.

Advantageously, the at least one isotope NMR relaxation time determined for the material sample, comprises at least one of the relaxation times determined for the reference samples.

In an embodiment, the processing of the set of material sample data to the calibrated mathematical function comprises applying the set of material sample data to a formula in the form of a best fit formula for the relationship between the respective sets of reference data and their associated known quantity of nitrogen containing units.

In an embodiment, the processing of the set of material sample data to the calibrated mathematical function comprises feeding the set of material sample data to a trained artificial intelligence data processor.

In an embodiment, the processing of the set of material sample data to the calibrated mathematical function comprises feeding the set of material sample data to a data processor obtainable by supervised or unsupervised machine learning, such as deep learning.

The invention also comprises a processor comprising an embedded calibrated mathematical function, wherein the embedded calibrated mathematical function represents relationship between data sets of at least one N isotope NMR intensity and at least one isotope NMR relaxation time in dependence of quantity of nitrogen containing units.

Advantageously, the processor is obtainable by the function generation method as described above.

The invention also comprises a system for performing a quantitative determination of nitrogen containing units in a material and/or in a material sample. The system comprises an NMR spectrometer and a computer system in data communication with the NMR spectrometer, wherein the computer system comprises a processor as described above.

Advantageously, the processor is programmed for or is trained for processing a set of material sample data comprising at least one N isotope NMR intensity and at least one isotope NMR relaxation time of a material sample and to perform a quantitative determination of the nitrogen containing units in said material sample or a material from which the material sample has been withdrawn.

As it will be realized by the skilled person, the method of the invention may be combined with additional NMR measurements involving NMR sensitivity enhancement such as enhancement involving polarization transfer, e.g. DEPT (Distortionless Enhancement by Polarization Transfer), INEPT (Insensitive nuclei enhanced by polarization transfer) or dynamic nuclear polarization (DNP). By using DEPT and/or INEPT combined with for example, ¹⁵N, ¹⁴N, or ¹³C NMR readings wherein the ¹³C NMR readings may provide concentrations of the presence of primary, secondary and tertiary carbon atoms (CH, CH₂ and CH₃ groups) may be determined. This determination may be combined with the determination of the method of the present invention and thereby further refine the determination of protein concentration.

All features of the inventions including ranges and preferred ranges can be combined in various ways within the scope of the invention, unless there are specific reasons not to combine such features.

### BRIEF DESCRIPTION OF EXAMPLES OF EMBODIMENTS OF THE INVENTION

The above and/or additional objects, features and advantages of embodiments of the present invention will be further elucidated by the following illustrative and non-limiting examples and description of embodiments of the present invention, with reference to the appended figures.

The figures are schematic and are not drawn to scale and may be simplified for clarity. Throughout, the same reference numerals are used for identical or corresponding parts.

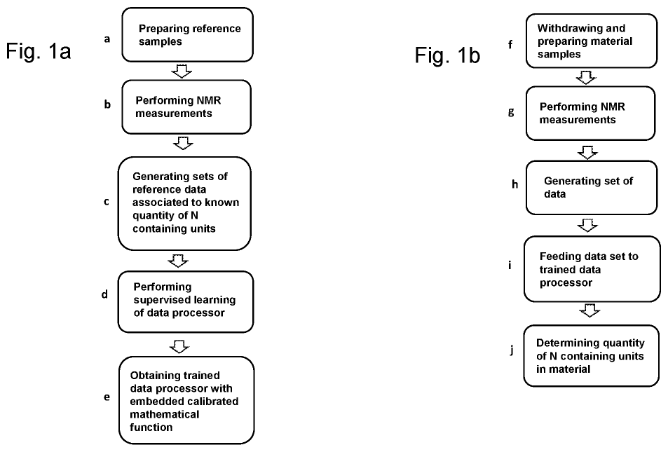

FIG. 1a and 1b are process diagrams for embodiments of respectively the function generation method and the nitrogen determination method.

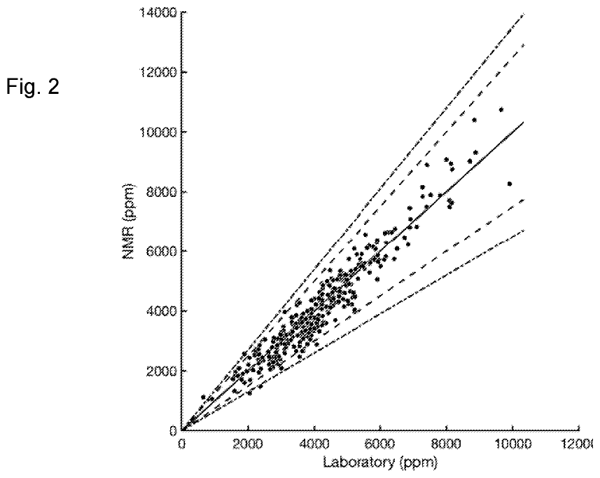

FIG. 2 is a diagram showing NMR determined total nitrogen content as a function of known total nitrogen content as obtained in example 1.

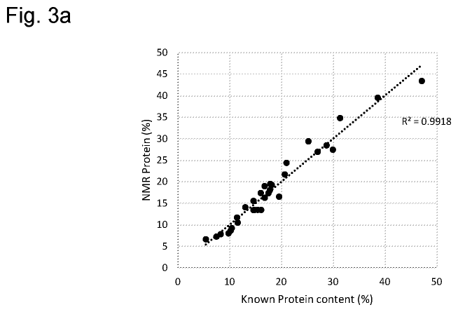

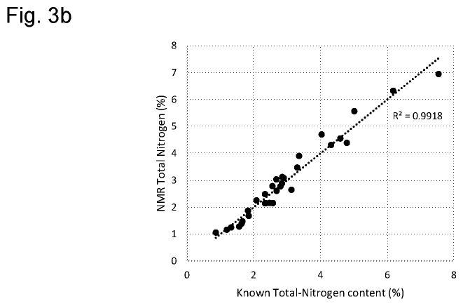

FIG. 3a is a diagram showing NMR determined protein content as a function of known protein content as obtained in example 2.

FIG. 3b is a diagram showing NMR determined total nitrogen content as a function of known total nitrogen content as obtained in example 2.

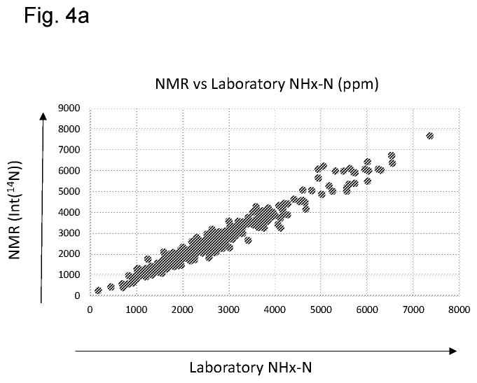

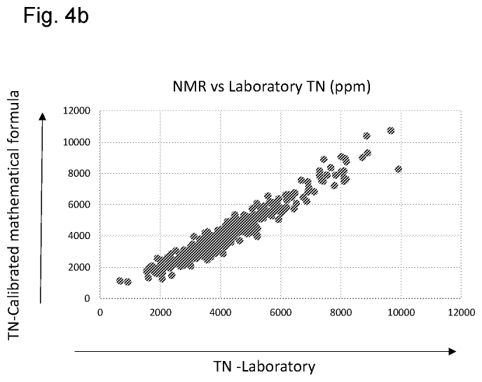

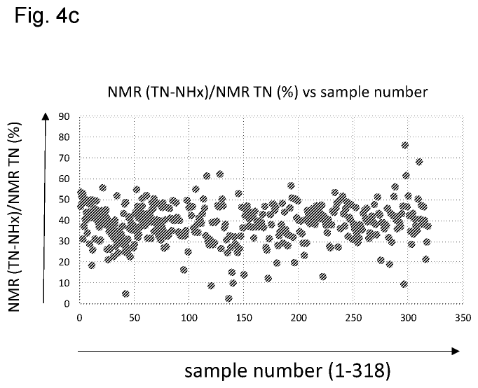

FIG. 4a is a diagram showing correlation between the nitrogen determination based on the intensity measurement (Int(¹⁴N)) and the laboratory determination of nitrogen content of the ammonium/ammonia components of the respective samples as obtained in example 3.

FIG. 4b is a diagram showing a correlation between the total nitrogen (TN) determined using the determined calibrated mathematical function and the total nitrogen determined in the laboratory as obtained in example 3.

FIG. 4c is a diagram showing the difference between the nitrogen determination based on the intensity measurement (Int(¹⁴N)) and the total nitrogen (TN) determined using the calibrated mathematical function as obtained in example 3.

FIG. 1a illustrates an embodiment of the function generation method for generating a data processor comprising an embedded calibrated mathematical function for performing a quantitative determination of nitrogen containing units in a sample. In step a, a number of reference samples are prepared as described above.

Each of the reference samples are subjected for NMR measurements comprising measurements of at least one N isotope NMR intensity and at least one isotope NMR relaxation time in step b.

For each of the reference samples, a reference data set of the measured at least one N isotope NMR intensity and the measured at least one isotope NMR relaxation time is generated in step c and associated to e data representing the respective known quantity of nitrogen containing units.

In step e the data sets with respective associated known quantity of nitrogen containing units are transmitted to the data processor for performing supervised learning of the data processor. The processor is trained to generate the calibrated mathematical function such that the function of a set of reference data it equal to the associated known quantity of nitrogen containing units. Thereby as illustrated in step e, the trained data processor comprising the embedded calibrated mathematical function for performing a quantitative determination of nitrogen containing units in a sample is obtained.

In FIG. 1b, step f, a material sample is withdrawn from a material and prepared in the same way that the reference samples were prepared.

In step g, the material sample is subjected for NMR measurements comprising measurements of at least one N isotope NMR intensity and at least one isotope NMR relaxation time and the measured at least one N isotope NMR intensity and the measured at least one isotope NMR relaxation time is coupled to form a set of data in step h. The set of data is hereafter fed to the trained processor in step i.

The trained data processor is processing the set of data according to the embedded calibrated mathematical function in step j and thereby determine the quantity of nitrogen containing units in the material.

### Example 1

218 reference samples of animal slurry were provided. The reference samples were obtained from various sources (pig, cattle, digester slurries, unspecified). The respective samples were homogenized and aspired into the NMR tube and ¹⁴N NMR intensity (Int(14N)) and proton T1 (T1(¹H)) and T2 (T2(¹H)) values measured and a data set was generated for each sample comprising the Int(¹⁴N), the T1 (¹H) and the T2(¹H) values.

The respective reference samples were subjected to a laboratory analysis, determining the total nitrogen content in parts per million (PPM). The laboratory determination was applied as the known quantity of total nitrogen.

The respective set of reference data and their associated known quantity of total nitrogen were processed according to the mathematical expression:

TN=k₁+Int(14N)[k₂+k₃1/T2(1H)+k₄(1/T2(1H))²+k₅1/T1(1H)+k₆(1/T1(1H))²],

where k₁-k₆ represents coefficient that are to be calibrated.

The coefficient k₁-k₆ were calibrated through a best-fit match established for the respective sets of reference data and their associated known quantity of total nitrogen. Thereby the calibrated mathematical function for the total nitrogen determination was generated.

Thereafter, for each of the samples, the set of reference data was processed according to the calibrated mathematical function. The obtained results are plotted in the diagram shown in FIG. 2. The x axis shows the known total nitrogen content (PPM) and the y-axis shows the NMR determined total nitrogen content (PPM) using the calibrated mathematical function for the total nitrogen determination.

### Example 2

31 reference samples of livestock feed were provided. The reference samples were various types of feedstuff including different grains (Rye, Wheat, Oat and Barley), a variety of commercial feed products for cattle, pigs, horses, poultry, rabbits/rodents and sheep (18 samples, complete and supplementary concentrates), prepared mixtures for pigs (4 samples) and for dairy cows (fresh and dried portion) obtained from local farms, soybean meal, feed peas and feed corn.

The reference samples were as listed in table 1:

TABLE 1

| Sample | |
|---|---|
| No. | Description |
| 1 | Rye. |
| 2 | Wheat. |
| 3 | Prepared feed mixture for pigs. Prepared of rye, wheat, soy oil, |
| | and a commercial feed product (sample 4) by local farmer. |
| 4 | Commercial feed product (supplementary feed) for pigs. |
| 5 | ‘NaturMüsli SOLO’. Complete feed product for horses. |
| 6 | Prepared feed mixture for pigs. |
| 7 | ‘LOGI svinefoder’. Complete feed for fattening pigs. |
| 8 | ‘Danish Vale’. Supplementary feed for calves. |
| 9 | ‘Komkalv T’. Supplementary feed for calves. |
| 10 | ‘Beefkalv Maxi’. Supplementary feed for calves. |
| 11 | ‘Svin Gain Enhed AU’. Complete feed for fattening pigs. |
| 12 | ‘Komkalv Start Valset’. Supplementary feed for calves. |
| 13 | ‘LH 2010 Classic’. Complete feed for fattening pigs. |
| 14 | ‘LH kvægblanding’. Supplementary feed for dairy cows. |
| 15 | ‘LH kalvefuldfoder’. Feed mixture for calves. |
| 16 | ‘LH fårefoder’. Supplementary feed for sheeps. |
| 17 | ‘SojaMax’. Supplementary feed for fattening pigs. |
| 18 | ‘Kalveplus’. Supplementary feed for calves. |
| 19 | Amequ lucerne pills. Supplementary feed for horses. |
| 20 | Barley. |
| 21 | Soybean meal. |
| 22 | Oat. |
| 23 | Feed corn. |
| 24 | Feed peas. |
| 25 | ‘Festival Exclusive’. Complete feed for rabbits and rodents. |
| 26 | ‘Herkules Hønsekorn’. Supplementary feed for poultry. |
| 27 | ‘Fuld-A-Pep’. Supplementary feed for egg-laying hens. |
| 28 | Feed mixture (total mixed ratio, TMR) for dairy cows. Dried |
| | version of sample 29. Fresh material dried at 60° C. for 48 h. |
| 29 | Feed mixture (total mixed ratio, TMR) for dairy cows. Fresh. |
| 30 | Prepared feed mixture for pigs. |
| 31 | Prepared feed mixture for pigs. |

Materials for reference samples 1-4, 6, and 28-31 were collected from local animal farms, whereas materials for reference samples 5 and 7-27 were purchased from various local feed stores.

The reference samples were comminuted and a portion of each sample were mixed with 9 parts by weight of water per part feed (18 parts water per part feed for sample 28) and were subject to a partially digestion using commercially available enzyme products (Protamex® and Flavourzyme®) for protein cleavage.

A portion of each reference sample was subjected to a Kjeldahl total-nitrogen analysis to thereby obtain a known quantity of total-nitrogen for each reference sample. The known quantity of total-nitrogen was determined as total-nitrogen content in % by weight of sample.

A known quantity of protein for each reference sample was calculated as protein content in % of sample by calculation from the known total-nitrogen content using Jones factor (6.25).

Each sample was subject to an NMR analysis. The NMR results were obtained using the combination of ¹⁴N NMR intensities and proton NMR T2 relaxation times. Both were determined in a static magnetic field of about 1.5 tesla and at a temperature of about 39° C. Thereby a set of NMR data set of reference data was generated for each reference sample comprising the ¹⁴N NMR intensity and the proton NMR T2 relaxation time for the reference sample in question.

The respective set of reference data and their associated known quantity of protein were processed according to the mathematical expression a*int(¹⁴N)+b*1/T2(¹H)+c, where the coefficients a, b and c were determined as a best fit to match the known quantity of protein. Thereby the calibrated mathematical function for the protein determination was generated.

Thereafter, for each of the samples, the set of reference data was processed according to the calibrated mathematical function. The obtained results are plotted in the diagram shown in FIG. 3a. The x axis shows the known protein content (wt %) and the y-axis shows the NMR determined protein content (wt %) using the calibrated mathematical function for the protein determination. R designate the trendline.

Thereafter, the respective set of reference data and their associated known quantity of total nitrogen were processed according to the mathematical expression a*int(¹⁴N)+b*1/T2(1H)+c, where the coefficients a, b and c were determined as a best-fit to match the known quantity of total nitrogen. Thereby the calibrated mathematical function for the total nitrogen determination was generated.

Thereafter, for each of the samples, the set of reference data was processed according to the calibrated mathematical function. The obtained results are plotted in the diagram shown in FIG. 3b. The x axis shows the known total nitrogen content (wt %) and the y-axis shows the NMR determined total nitrogen content (wt %) using the calibrated mathematical function for the total nitrogen determination. R designate the trendline.

### Example 3

318 reference samples of animal slurry were provided. The reference samples were obtained from various sources as listed in table 2. In addition 79 mixed samples were generated, each mixed sample was a blend of six equally sized portions of original manures samples.

The respective samples were homogenized and aspired into the NMR tube and ¹⁴N NMR intensity (Int(¹⁴N)) and proton T1 (T1(¹H)) and T2 (T2(¹H)) values measured and a data set was generated for each sample comprising the Int(¹⁴N), the T1(¹H) and the T2(¹H) values.

The respective reference samples were subjected to wet chemistry laboratory analysis, determining the nitrogen content in PPM originating from ammonium/ammonia components (Lab-NH_{X}-N) and the total nitrogen content (Lab-TN) in PPM. The total nitrogen content laboratory determination was applied as the known quantity of total nitrogen.

The respective set of reference data and their associated known quantity of total nitrogen were processed according to the mathematical expression:

TN=k₁+Int(14N)[k₂+k₃1/T2(1H)+k₄(1/T2(1H))²+k₅1/T1(1H)+k₆(1/T1(1H))²],

where TN equals Lab-TN, and k₁-k₆ represents coefficient that are to be calibrated.

The coefficient k₁-k₆ were calibrated through a best-fit match established for the respective sets of reference data and their associated known quantity of total nitrogen. Thereby the calibrated mathematical function for the total nitrogen determination was generated.

The coefficients k₁-k₆ were determined to be as follows:

| k₁ | k₂ | k₃ | k₄ | k₅ | k₆ |
|---|---|---|---|---|---|
| 1403 | 0.445 | 0.075 | −0.001 | −0.059 | 0.001 |

The final calibrated mathematical function for the total nitrogen determination was therefore as follows:

TN=1403+Int(14N)[0.445+0.075(1/T2(1H))−0.001(1/T2(1H))²−0.059(1/T1(1H))+0.001(1/T1(1H))²]

Thereafter, for each of the samples, the set of reference data was processed according to the calibrated mathematical function. The obtained results of total nitrogen (TN) are plotted in the diagram shown in table 2 in the column NMR-TN (ppm).

The intensity determinations Int(¹⁴N) for each samples were correlated to the laboratory analysis of the nitrogen content originating from ammonium/ammonia components (Lab-NHₓ-N). The results are listed in table 2 in the column NMR-NHₓ-N (ppm).

FIG. 4a show a correlation between the nitrogen determination based on the intensity measurement (Int(¹⁴N)) without the addition from the relaxation determination and the laboratory determination of nitrogen content of the ammonium/ammonia components of the respective samples. It can be seen that there is a significant correlation, indicating that by basing the nitrogen content on the NMR intensity measurement, likely only the nitrogen content of the ammonium/ammonia components is detected. In cases where the relation between nitrogen of the ammonium/ammonia components and the total nitrogen is a linear relation, the total nitrogen could be determined by multiplying the nitrogen of the ammonium/ammonia components by a certain factor. However, for most biological product and derivatives thereof there is not a linear relation between nitrogen of the ammonium/ammonia components and the total nitrogen and such a determination would therefore be highly inaccurate and in many situations completely useless.

FIG. 4b show a correlation between the total nitrogen (TN) determined using the above determined calibrated mathematical function and the total nitrogen determined in the laboratory as described above. It can be seen that there is a significant correlation, indicating that the determined calibrated mathematical function and the use thereof provide a highly accurate determination of the total nitrogen. This demonstrate that the method of the invention provides a large improvement relative to prior art methods, both in respect of accuracy as well as being both very fast and relatively simple.

FIG. 4c show the difference (in %) between the nitrogen determination based on the intensity measurement (Int(⁴N)) without the addition from the relaxation determination and the total nitrogen (TN) determined using the above determined calibrated mathematical function. Clearly it is a chaotic image with practically no correlation. This is a clear demonstration that basing the total nitrogen determination on the NMR intensity determination without adding a contribution from the relaxation determination is practically useless. In addition, attempting to improve the result by multiplying the nitrogen of the ammonium/ammonia components by a certain factor would not result in a method providing a highly accurate determination of the total nitrogen as achieved using embodiments of the present invention.

TABLE 2

| | | Laboratory | | NMR | |
|---|---|---|---|---|---|
| | | NHx-N | TN | NHx-N | TN |
| Sample # | Type | (ppm) | (ppm) | (ppm) | (ppm) |
| 1 | Unknown | 1544 | 2752 | 1128 | 2124 |
| 2 | Digester | 1538 | 3556 | 1283 | 2470 |
| 3 | Pig | 4536 | 5565 | 4516 | 6564 |
| 4 | Pig | 2863 | 3561 | 2275 | 3626 |
| 5 | Cattle | 1972 | 3622 | 2168 | 3656 |
| 6 | Pig | 3421 | 5149 | 2657 | 4446 |
| 7 | Pig | 5556 | 7528 | 5203 | 7902 |
| 8 | Pig | 2574 | 4058 | 1831 | 3569 |
| 9 | Pig | 1827 | 2877 | 1949 | 2739 |
| 10 | Pig | 2925 | 4748 | 2773 | 4743 |
| 11 | Pig | 6530 | 9906 | 6736 | 8272 |
| 12 | Pig | 3270 | 4179 | 3183 | 4299 |
| 13 | Unknown | 2476 | 3373 | 2210 | 3801 |
| 14 | Pig | 2155 | 2892 | 2111 | 3071 |
| 15 | Cattle | 1540 | 2759 | 1499 | 2975 |
| 16 | Pig | 1775 | 1894 | 1496 | 2570 |
| 17 | Digester | 2472 | 4168 | 2475 | 4091 |
| 18 | Pig | 2153 | 2511 | 2130 | 3052 |
| 19 | Cattle | 2004 | 3125 | 2204 | 3184 |
| 20 | Unknown | 2496 | 4485 | 2429 | 4402 |
| 21 | Cattle | 1853 | 3644 | 1723 | 3902 |
| 22 | Digester | 2531 | 4223 | 2960 | 4917 |
| 23 | Pig | 2272 | 3344 | 2176 | 3552 |
| 24 | Pig | 1909 | 3666 | 1457 | 2663 |
| 25 | Pig | 3659 | 4863 | 3870 | 5249 |
| 26 | Pig | 3302 | 4000 | 3462 | 4401 |
| 27 | Cattle | 3004 | 4422 | 3589 | 4909 |
| 28 | Cattle | 3424 | 4870 | 3756 | 5099 |
| 29 | Pig | 6030 | 8708 | 5994 | 9023 |
| 30 | Digester | 2660 | 4240 | 2777 | 4339 |
| 31 | Pig | 3817 | 4778 | 4067 | 5273 |
| 32 | Cattle | 2149 | 3841 | 2189 | 3667 |
| 33 | Pig | 2864 | 3663 | 2710 | 3918 |
| 34 | Cattle | 2377 | 4241 | 2280 | 4756 |
| 35 | Unknown | 1188 | 1623 | 1294 | 1831 |
| 36 | Cattle | 1015 | 1619 | 1267 | 1953 |
| 37 | Pig | 2935 | 4894 | 2895 | 4142 |
| 38 | Pig | 1790 | 2866 | 1489 | 2240 |
| 39 | Digester | 3776 | 5790 | 3839 | 6135 |
| 40 | Cattle | 1581 | 2847 | 1337 | 2365 |
| 41 | Cattle | 2256 | 3989 | 1734 | 3334 |
| 42 | Unknown | 1294 | 2653 | 1208 | 2360 |
| 43 | Digester | 5730 | 8091 | 5398 | 7728 |
| 44 | Pig | 3410 | 5084 | 3584 | 5205 |
| 45 | Cattle | 1934 | 3723 | 2050 | 3493 |
| 46 | Cattle | 2777 | 4931 | 2874 | 4943 |
| 47 | Digester | 4800 | 7289 | 5053 | 7848 |
| 48 | Digester | 5559 | 7817 | 5027 | 7890 |
| 49 | Pig | 1795 | 2323 | 1880 | 2575 |
| 50 | Digester | 5610 | 8105 | 5355 | 7503 |
| 51 | Pig | 2991 | 5076 | 3024 | 4661 |
| 52 | Cattle | 1610 | 3066 | 1562 | 3468 |
| 53 | Unknown | 2584 | 4726 | 2278 | 4283 |
| 54 | Cattle | 1616 | 3130 | 1855 | 3160 |
| 55 | Pig | 4003 | 6243 | 3854 | 6646 |
| 56 | Cattle | 1718 | 3173 | 1811 | 3218 |
| 57 | Cattle | 2137 | 4220 | 2082 | 4233 |
| 58 | Cattle | 2433 | 4286 | 2061 | 3638 |
| 59 | Digester | 2917 | 4955 | 2868 | 4844 |
| 60 | Pig | 2362 | 3312 | 2362 | 3789 |
| 61 | Cattle | 1234 | 2316 | 1133 | 2366 |
| 62 | Digester | 6545 | 8880 | 6371 | 9315 |
| 63 | Pig | 2537 | 3967 | 2111 | 3737 |
| 64 | Unknown | 1701 | 3208 | 1653 | 2919 |
| 65 | Pig | 3302 | 5097 | 3547 | 5186 |
| 66 | Digester | 1970 | 4075 | 1469 | 2875 |
| 67 | Cattle | 1303 | 2460 | 1276 | 2357 |
| 68 | Cattle | 945 | 1600 | 909 | 1837 |
| 69 | Pig | 1563 | 2776 | 1506 | 2468 |
| 70 | Pig | 2674 | 4790 | 2986 | 4617 |
| 71 | Unknown | 1022 | 1964 | 1032 | 1992 |
| 72 | Pig | 3486 | 4839 | 3495 | 5191 |
| 73 | Digester | 3766 | 6182 | 3497 | 5827 |
| 74 | Pig | 2545 | 3849 | 2374 | 3878 |
| 75 | Cattle | 1789 | 3457 | 2071 | 3864 |
| 76 | Cattle | 1626 | 3168 | 1471 | 2861 |
| 77 | Pig | 3276 | 4772 | 3473 | 5177 |
| 78 | Pig | 4654 | 6895 | 4492 | 6813 |
| 79 | Pig | 3029 | 4219 | 3289 | 4536 |
| 80 | Cattle | 1211 | 2041 | 1307 | 2440 |
| 81 | Pig | 2745 | 4218 | 2733 | 4068 |
| 82 | Cattle | 1607 | 3109 | 1400 | 2589 |
| 83 | Cattle | 2055 | 3092 | 1813 | 3085 |
| 84 | Unknown | 2009 | 3037 | 2124 | 3280 |
| 85 | Pig | 1576 | 2839 | 1340 | 2663 |
| 86 | Unknown | 1595 | 2313 | 1577 | 2631 |
| 87 | Cattle | 1960 | 3560 | 1876 | 3167 |
| 88 | Cattle | 1537 | 3134 | 1491 | 2902 |
| 89 | Digester | 2942 | 4517 | 2972 | 5088 |
| 90 | Digester | 3780 | 5666 | 4039 | 6180 |
| 91 | Pig | 3746 | 5930 | 3515 | 5867 |
| 92 | Unknown | 3060 | 4383 | 3354 | 4996 |
| 93 | Pig | 3171 | 4157 | 3111 | 4630 |
| 94 | Pig | 2154 | 2752 | 1862 | 2799 |
| 95 | Unknown | 4599 | 6013 | 4589 | 5488 |
| 96 | Pig | 2870 | 4634 | 2891 | 4304 |
| 97 | Pig | 3734 | 5384 | 3563 | 5501 |
| 98 | Cattle | 1507 | 3153 | 1457 | 2904 |
| 99 | Pig | 1463 | 1726 | 1560 | 2082 |
| 100 | Digester | 1500 | 2376 | 1242 | 2313 |
| 101 | Cattle | 1375 | 2312 | 1197 | 2253 |
| 102 | Digester | 3033 | 4461 | 2789 | 4848 |
| 103 | Cattle | 2339 | 4520 | 2255 | 4237 |
| 104 | Cattle | 3232 | 5311 | 3225 | 5087 |
| 105 | Pig | 4123 | 5965 | 3731 | 5704 |
| 106 | Cattle | 1210 | 2148 | 909 | 2027 |
| 107 | Cattle | 2862 | 4912 | 2843 | 4597 |
| 108 | Pig | 3311 | 4564 | 3294 | 5022 |
| 109 | Digester | 1778 | 3012 | 1795 | 3050 |
| 110 | Cattle | 1576 | 2990 | 1734 | 2911 |
| 111 | Digester | 3781 | 5867 | 3723 | 6076 |
| 112 | Unknown | 2370 | 4443 | 2290 | 4043 |
| 113 | Cattle | 1851 | 3917 | 1921 | 3878 |
| 114 | Cattle | 2178 | 4143 | 1790 | 3319 |
| 115 | Unknown | 3180 | 5224 | 2999 | 4472 |
| 116 | Cattle | 940 | 1891 | 615 | 1595 |
| 117 | Unknown | 2596 | 3592 | 2438 | 3499 |
| 118 | Unknown | 3959 | 5407 | 4018 | 5618 |
| 119 | Digester | 3799 | 5842 | 3937 | 5713 |
| 120 | Digester | 5053 | 7111 | 6227 | 6826 |
| 121 | Unknown | 3108 | 5098 | 2974 | 4891 |
| 122 | Digester | 7362 | 9654 | 7681 | 10745 |
| 123 | Pig | 1201 | 1542 | 1224 | 1732 |
| 124 | Cattle | 2212 | 4027 | 2080 | 3426 |
| 125 | Unknown | 1667 | 2847 | 1683 | 2796 |
| 126 | Unknown | 1773 | 3317 | 1917 | 3637 |
| 127 | Cattle | 1936 | 3800 | 1539 | 2886 |
| 128 | Pig | 450 | 654 | 423 | 1125 |
| 129 | Unknown | 3730 | 5346 | 4074 | 5552 |
| 130 | Cattle | 1906 | 4342 | 1786 | 3600 |
| 131 | Unknown | 1817 | 3450 | 1407 | 2665 |
| 132 | Pig | 2628 | 3106 | 2512 | 3964 |
| 133 | Cattle | 1250 | 2346 | 1762 | 2856 |
| 134 | Unknown | 2439 | 3772 | 2418 | 3498 |
| 135 | Pig | 3817 | 4778 | 4027 | 5345 |
| 136 | Unknown | 2665 | 3080 | 3089 | 3173 |
| 137 | Cattle | 2640 | 4573 | 3192 | 4753 |
| 138 | Pig | 2711 | 3548 | 2660 | 3658 |
| 139 | Digester | 3595 | 4798 | 4271 | 5038 |
| 140 | Unknown | 4936 | 6458 | 6080 | 6756 |
| 141 | Pig | 2962 | 4045 | 2855 | 4218 |
| 142 | Unknown | 3816 | 5535 | 3852 | 5411 |
| 143 | Pig | 3706 | 4466 | 3852 | 5358 |
| 144 | Digester | 4942 | 7401 | 5651 | 7508 |
| 145 | Cattle | 1542 | 3101 | 1285 | 2738 |
| 146 | Unknown | 4172 | 5381 | 4218 | 5740 |
| 147 | Digester | 2353 | 3597 | 2195 | 3259 |
| 148 | Cattle | 1804 | 3557 | 1510 | 2824 |
| 149 | Digester | 3279 | 5155 | 3351 | 5282 |
| 150 | Unknown | 2572 | 3069 | 2873 | 3346 |
| 151 | Unknown | 2090 | 3793 | 1815 | 3159 |
| 152 | Digester | 1716 | 3560 | 1618 | 2957 |
| 153 | Digester | 2314 | 5210 | 2101 | 3972 |
| 154 | Digester | 2329 | 3694 | 2156 | 3445 |
| 155 | Cattle | 1607 | 2874 | 1569 | 2655 |
| 156 | Unknown | 1979 | 3716 | 1819 | 3244 |
| 157 | Cattle | 2234 | 4018 | 2146 | 3405 |
| 158 | Cattle | 1837 | 3785 | 1669 | 2897 |
| 159 | Unknown | 3822 | 5693 | 3805 | 5575 |
| 160 | Digester | 1701 | 3324 | 1852 | 3338 |
| 161 | Cattle | 3764 | 5200 | 3823 | 6079 |
| 162 | Cattle | 2312 | 4247 | 2165 | 3595 |
| 163 | Digester | 2691 | 4390 | 2567 | 4081 |
| 164 | Digester | 4273 | 6741 | 3895 | 6477 |
| 165 | Cattle | 2424 | 4353 | 2556 | 4146 |
| 166 | Pig | 1890 | 3137 | 1697 | 2784 |
| 167 | Cattle | 1879 | 3199 | 1714 | 3012 |
| 168 | Pig | 2273 | 3292 | 1925 | 3040 |
| 169 | Cattle | 1817 | 3785 | 1741 | 3277 |
| 170 | Pig | 3452 | 5045 | 3565 | 4900 |
| 171 | Pig | 1888 | 2232 | 1969 | 2655 |
| 172 | Pig | 2757 | 2996 | 2879 | 3284 |
| 173 | Pig | 3028 | 4741 | 3082 | 4493 |
| 174 | Cattle | 2470 | 4411 | 2261 | 3963 |
| 175 | Unknown | 6008 | 8849 | 6439 | 10408 |
| 176 | Unknown | 1736 | 3203 | 1517 | 2916 |
| 177 | Cattle | 1982 | 3855 | 2041 | 3921 |
| 178 | Cattle | 1372 | 2839 | 1357 | 2473 |
| 179 | Cattle | 1505 | 3108 | 1555 | 2899 |
| 180 | Pig | 5312 | 6895 | 5993 | 7466 |
| 181 | Unknown | 4185 | 5265 | 3903 | 5429 |
| 182 | Unknown | 3356 | 4977 | 3496 | 5208 |
| 183 | Digester | 4417 | 6925 | 4634 | 7094 |
| 184 | Pig | 3030 | 4263 | 3007 | 4862 |
| 185 | Cattle | 1683 | 2855 | 1431 | 2770 |
| 186 | Cattle | 2351 | 3617 | 2672 | 3774 |
| 187 | Cattle | 1396 | 2715 | 1272 | 2278 |
| 188 | Pig | 2736 | 3910 | 2515 | 3917 |
| 189 | Pig | 2872 | 4142 | 2906 | 4383 |
| 190 | Digester | 2348 | 3442 | 2574 | 3574 |
| 191 | Pig | 4674 | 6855 | 4162 | 6220 |
| 192 | Unknown | 2192 | 3804 | 1929 | 3583 |
| 193 | Pig | 694 | 1594 | 572 | 1325 |
| 194 | Cattle | 1856 | 4246 | 1879 | 3829 |
| 195 | Pig | 5953 | 8138 | 6082 | 8948 |
| 196 | Unknown | 1825 | 2968 | 1908 | 2382 |
| 197 | Cattle | 1331 | 2880 | 1415 | 2851 |
| 198 | Cattle | 2744 | 4123 | 2256 | 3856 |
| 199 | Pig | 2842 | 5236 | 2725 | 5403 |
| 200 | Digester | 2236 | 4482 | 2453 | 4098 |
| 201 | Pig | 5710 | 8000 | 5921 | 9077 |
| 202 | Unknown | 2880 | 4402 | 2725 | 4526 |
| 203 | Cattle | 2853 | 4546 | 3050 | 4610 |
| 204 | Pig | 3012 | 3907 | 3088 | 4359 |
| 205 | Pig | 2695 | 4099 | 2673 | 3488 |
| 206 | Pig | 3303 | 4974 | 2995 | 5035 |
| 207 | Pig | 3151 | 4186 | 3161 | 4470 |
| 208 | Cattle | 1491 | 2670 | 1133 | 2054 |
| 209 | Digester | 2941 | 4732 | 2447 | 4311 |
| 210 | Cattle | 1979 | 3637 | 2026 | 3299 |
| 211 | Cattle | 1430 | 2638 | 1242 | 2221 |
| 212 | Digester | 2305 | 3891 | 2227 | 3770 |
| 213 | Cattle | 1407 | 2754 | 1234 | 2278 |
| 214 | Cattle | 2186 | 3896 | 1816 | 3181 |
| 215 | Cattle | 2421 | 3913 | 2510 | 4064 |
| 216 | Cattle | 1103 | 1698 | 972 | 1841 |
| 217 | Digester | 2789 | 4756 | 2730 | 4653 |
| 218 | Digester | 3017 | 5121 | 2318 | 4215 |
| 219 | Digester | 1794 | 3337 | 1847 | 3134 |
| 220 | Cattle | 1882 | 3652 | 1977 | 3492 |
| 221 | Cattle | 1817 | 3607 | 1861 | 3549 |
| 222 | Pig | 1955 | 2195 | 2194 | 2527 |
| 223 | Cattle | 2254 | 4000 | 2151 | 3721 |
| 224 | Digester | 2496 | 4579 | 2671 | 4445 |
| 225 | Digester | 2202 | 3480 | 2609 | 4199 |
| 226 | Digester | 5250 | 8166 | 5021 | 7634 |
| 227 | Unknown | 2094 | 3876 | 1809 | 3042 |
| 228 | Pig | 3827 | 5942 | 4076 | 5645 |
| 229 | Digester | 1708 | 2430 | 1784 | 2443 |
| 230 | Unknown | 1080 | 1847 | 1179 | 1902 |
| 231 | Digester | 2592 | 4629 | 2049 | 3698 |
| 232 | Cattle | 1553 | 2759 | 1281 | 2290 |
| 233 | Cattle | 1961 | 3735 | 1734 | 3735 |
| 234 | Cattle | 1911 | 3419 | 1855 | 3439 |
| 235 | Cattle | 1043 | 2328 | 1311 | 2548 |
| 236 | Pig | 4201 | 6512 | 4422 | 6087 |
| 237 | Cattle | 1557 | 2973 | 1091 | 2170 |
| 238 | Digester | 1795 | 3156 | 2039 | 3201 |
| 239 | Cattle | 1485 | 3381 | 1387 | 2812 |
| 240 | Cattle | 1349 | 3007 | 1003 | 2083 |
| 241 | Cattle | 2239 | 4077 | 2044 | 3605 |
| 242 | Cattle | 2051 | 3836 | 2048 | 3277 |
| 243 | Digester | 1398 | 2929 | 1343 | 2479 |
| 244 | Cattle | 1598 | 3643 | 1357 | 2665 |
| 245 | Digester | 6010 | 7288 | 5504 | 8157 |
| 246 | Cattle | 2152 | 3889 | 2102 | 3603 |
| 247 | Pig | 2761 | 3555 | 2535 | 4264 |
| 248 | Digester | 1344 | 2629 | 1295 | 2474 |
| 249 | Digester | 6300 | 8176 | 6031 | 8754 |
| 250 | Cattle | 2140 | 4230 | 2172 | 3533 |
| 251 | Digester | 3708 | 5440 | 3763 | 5903 |
| 252 | Digester | 2007 | 4233 | 2336 | 4355 |
| 253 | Pig | 2096 | 2981 | 2125 | 3210 |
| 254 | Pig | 2239 | 3660 | 2171 | 3078 |
| 255 | Digester | 6242 | 7422 | 6079 | 8899 |
| 256 | Unknown | 2498 | 4417 | 2437 | 3927 |
| 257 | Pig | 3737 | 5711 | 3548 | 5615 |
| 258 | Unknown | 3769 | 5924 | 3251 | 5053 |
| 259 | Cattle | 1815 | 3290 | 1711 | 3030 |
| 260 | Cattle | 1813 | 3459 | 1891 | 3435 |
| 261 | Unknown | 3078 | 5174 | 2723 | 4612 |
| 262 | Cattle | 1608 | 2844 | 1413 | 2614 |
| 263 | Cattle | 1313 | 2381 | 1256 | 2077 |
| 264 | Unknown | 3271 | 4860 | 3005 | 4391 |
| 265 | Pig | 2838 | 4552 | 2750 | 4178 |
| 266 | Pig | 3537 | 4758 | 3410 | 5070 |
| 267 | Pig | 2698 | 3913 | 2072 | 3587 |
| 268 | Digester | 2206 | 4021 | 2287 | 3761 |
| 269 | Cattle | 1230 | 2319 | 1018 | 1950 |
| 270 | Unknown | 2969 | 4513 | 2689 | 4355 |
| 271 | Pig | 2722 | 3782 | 2666 | 3996 |
| 272 | Cattle | 916 | 1799 | 835 | 1719 |
| 273 | Cattle | 1606 | 2608 | 1485 | 2629 |
| 274 | Unknown | 1973 | 3282 | 1851 | 3232 |
| 275 | Digester | 3561 | 4940 | 4113 | 5209 |
| 276 | Pig | 3198 | 5394 | 3344 | 5486 |
| 277 | Digester | 2783 | 4690 | 3076 | 5049 |
| 278 | Pig | 2904 | 4484 | 2626 | 4113 |
| 279 | Unknown | 3267 | 5536 | 3456 | 5590 |
| 280 | Digester | 4163 | 6155 | 4133 | 6628 |
| 281 | Cattle | 1841 | 3721 | 1808 | 3346 |
| 282 | Pig | 2985 | 4233 | 3098 | 4555 |
| 283 | Unknown | 3207 | 4579 | 3573 | 4417 |
| 284 | Unknown | 2139 | 3877 | 1921 | 3404 |
| 285 | Pig | 2935 | 4139 | 3104 | 4418 |
| 286 | Cattle | 1636 | 3487 | 1830 | 3181 |
| 287 | Cattle | 1747 | 3578 | 1739 | 3596 |
| 288 | Cattle | 835 | 2012 | 963 | 2204 |
| 289 | Pig | 2569 | 4005 | 2262 | 3781 |
| 290 | Digester | 3527 | 5903 | 4021 | 6299 |
| 291 | Pig | 2880 | 5029 | 2454 | 4248 |
| 292 | Digester | 3401 | 5043 | 3501 | 5748 |
| 293 | Digester | 3647 | 5273 | 3699 | 5897 |
| 294 | Pig | 4126 | 6432 | 3254 | 5746 |
| 295 | Pig | 1507 | 2726 | 1476 | 2785 |
| 296 | Pig | 2308 | 2783 | 2799 | 3095 |
| 297 | Unknown | 175 | 911 | 252 | 1062 |
| 298 | Cattle | 823 | 2375 | 567 | 1479 |
| 299 | Cattle | 1898 | 3627 | 1928 | 3618 |
| 300 | Cattle | 1001 | 2067 | 815 | 1695 |
| 301 | Digester | 3640 | 6125 | 3286 | 5711 |
| 302 | Pig | 1703 | 2315 | 1770 | 2717 |
| 303 | Pig | 3873 | 5690 | 3771 | 5287 |
| 304 | Cattle | 1594 | 4104 | 2100 | 3721 |
| 305 | Digester | 4280 | 6349 | 4417 | 6646 |
| 306 | Pig | 2771 | 5006 | 2566 | 4335 |
| 307 | Digester | 2109 | 3335 | 2062 | 3301 |
| 308 | Digester | 3330 | 5103 | 3459 | 5349 |
| 309 | Cattle | 1826 | 3795 | 1785 | 3598 |
| 310 | Digester | 716 | 2053 | 400 | 1260 |
| 311 | Pig | 3913 | 5924 | 3775 | 6375 |
| 312 | Cattle | 2732 | 5218 | 2122 | 4031 |
| 313 | Digester | 2098 | 3909 | 2196 | 3560 |
| 314 | Cattle | 1903 | 3996 | 1822 | 3417 |
| 315 | Digester | 3586 | 5607 | 3661 | 6117 |
| 316 | Pig | 3632 | 4604 | 3731 | 4753 |
| 317 | Pig | 4216 | 6198 | 4416 | 6292 |
| 318 | Digester | 3398 | 5484 | 3445 | 5500 |
| 1 | Mixture | 1180 | 2271 | 1042 | 2251 |
| 2 | Mixture | 1259 | 2509 | 1078 | 2228 |
| 3 | Mixture | 1389 | 2667 | 1199 | 2551 |
| 4 | Mixture | 1543 | 3057 | 1293 | 2609 |
| 5 | Mixture | 1390 | 2755 | 1326 | 2631 |
| 6 | Mixture | 1603 | 2898 | 1607 | 2875 |
| 7 | Mixture | 1668 | 3211 | 1289 | 2571 |
| 8 | Mixture | 1553 | 2966 | 1505 | 2696 |
| 9 | Mixture | 1751 | 3311 | 1855 | 3571 |
| 10 | Mixture | 1887 | 3335 | 1547 | 3008 |
| 11 | Mixture | 1840 | 3316 | 1562 | 3128 |
| 12 | Mixture | 1825 | 3323 | 1654 | 3000 |
| 13 | Mixture | 1840 | 3327 | 1678 | 2861 |
| 14 | Mixture | 1913 | 3749 | 1998 | 3678 |
| 15 | Mixture | 1749 | 3302 | 2020 | 3477 |
| 16 | Mixture | 1916 | 3330 | 1844 | 3348 |
| 17 | Mixture | 1912 | 3383 | 1985 | 3266 |
| 18 | Mixture | 2017 | 3160 | 1988 | 3153 |
| 19 | Mixture | 2210 | 3801 | 2319 | 3812 |
| 20 | Mixture | 2298 | 3704 | 2309 | 4026 |
| 21 | Mixture | 2345 | 4029 | 2330 | 4126 |
| 22 | Mixture | 2453 | 3863 | 2360 | 3825 |
| 23 | Mixture | 2581 | 4393 | 2648 | 4622 |
| 24 | Mixture | 2584 | 4386 | 2394 | 4040 |
| 25 | Mixture | 2592 | 4165 | 2445 | 4153 |
| 26 | Mixture | 2598 | 4112 | 2463 | 3943 |
| 27 | Mixture | 2770 | 4197 | 2802 | 4297 |
| 28 | Mixture | 2993 | 4627 | 2905 | 4762 |
| 29 | Mixture | 3105 | 4580 | 2869 | 4439 |
| 30 | Mixture | 3110 | 5142 | 3312 | 5035 |
| 31 | Mixture | 3166 | 4749 | 3122 | 4591 |
| 32 | Mixture | 3622 | 5481 | 3448 | 5617 |
| 33 | Mixture | 3528 | 5074 | 3546 | 4908 |
| 34 | Mixture | 3686 | 5349 | 3957 | 5713 |
| 35 | Mixture | 3855 | 5372 | 4213 | 5583 |
| 36 | Mixture | 3934 | 5757 | 4020 | 5754 |
| 37 | Mixture | 4086 | 6362 | 4333 | 6480 |
| 38 | Mixture | 4607 | 6678 | 5074 | 7562 |
| 39 | Mixture | 5173 | 7351 | 5286 | 7561 |
| 40 | Mixture | 5487 | 7658 | 5986 | 8367 |
| 41 | Mixture | 5625 | 8094 | 6112 | 8158 |
| 42 | Mixture | 1473 | 1833 | 1560 | 1641 |
| 43 | Mixture | 1923 | 2836 | 2015 | 2765 |
| 44 | Mixture | 2332 | 3377 | 2589 | 3425 |
| 45 | Mixture | 2231 | 3581 | 2235 | 3525 |
| 46 | Mixture | 2623 | 3804 | 2812 | 3639 |
| 47 | Mixture | 2133 | 3416 | 1989 | 3259 |
| 48 | Mixture | 2437 | 3755 | 2309 | 3706 |
| 49 | Mixture | 2463 | 3688 | 2437 | 3904 |
| 50 | Mixture | 2000 | 3272 | 1946 | 3041 |
| 51 | Mixture | 2240 | 3653 | 1956 | 3490 |
| 52 | Mixture | 1809 | 3038 | 1627 | 2854 |
| 53 | Mixture | 2660 | 4014 | 2661 | 3917 |
| 54 | Mixture | 2174 | 3663 | 2266 | 3403 |
| 55 | Mixture | 2116 | 3528 | 1935 | 3071 |
| 56 | Mixture | 2169 | 3839 | 2065 | 3628 |
| 57 | Mixture | 1882 | 3519 | 1572 | 2963 |
| 58 | Mixture | 2088 | 3477 | 2175 | 3571 |
| 59 | Mixture | 2420 | 4017 | 2289 | 3746 |
| 60 | Mixture | 2363 | 4019 | 2110 | 3568 |
| 61 | Mixture | 2157 | 3689 | 2045 | 3599 |
| 62 | Mixture | 2402 | 4148 | 2425 | 4071 |
| 63 | Mixture | 1914 | 3682 | 2031 | 3599 |
| 64 | Mixture | 2285 | 3789 | 2111 | 3703 |
| 65 | Mixture | 2292 | 4171 | 2334 | 3854 |
| 66 | Mixture | 2169 | 3859 | 1681 | 3068 |
| 67 | Mixture | 2511 | 4482 | 2703 | 4450 |
| 68 | Mixture | 2921 | 4211 | 2864 | 4407 |
| 69 | Mixture | 2582 | 4129 | 2214 | 3711 |
| 70 | Mixture | 2663 | 4005 | 2385 | 4007 |
| 71 | Mixture | 2720 | 4622 | 2776 | 4475 |
| 72 | Mixture | 3142 | 4681 | 2872 | 4558 |
| 73 | Mixture | 3738 | 5732 | 3641 | 5467 |
| 74 | Mixture | 3686 | 5424 | 3566 | 5154 |
| 75 | Mixture | 3096 | 4792 | 3117 | 4970 |
| 76 | Mixture | 3848 | 5831 | 3590 | 5601 |
| 77 | Mixture | 5739 | 8004 | 5912 | 8092 |
| 78 | Mixture | 4069 | 6082 | 3415 | 5733 |
| 79 | Mixture | 5018 | 7776 | 4875 | 7224 |

1.-64. (canceled)

65. A method of generating a calibrated mathematical function for performing a quantitative determination of nitrogen containing units in a sample, the method comprising:
providing a number M of reference samples with different and known quantity of nitrogen containing units, wherein the number M is at least 2;
for each of the reference samples acquiring a set of reference data comprising at least one N isotope intensity selected from a ¹⁴N isotope NMR intensity and a ¹⁵N isotope NMR intensity and at least one isotope NMR relaxation time and wherein each set of reference data is associated to the respective known quantity of nitrogen containing units; and
processing the sets of reference data for the M reference samples and their respective associated known quantity of nitrogen containing units to generate the calibrated mathematical function.

66. The function generation method of claim 65, wherein the nitrogen containing units are selected from nitrogen atoms, nitrogen containing molecules, total nitrogen units (TN), protein, amino acids, amines, amides, nucleic acids, urea, ammonium, nitrate, nitrite or a combination thereof.

67. The function generation method of claim 65, wherein the at least one isotope NMR relaxation time comprises at least one relaxation time for at least one of ¹H, ²H, ⁶Li, ⁷Li, ¹⁰B, ¹¹B, ¹⁴N, ¹⁵N, ²³Na, ³¹P, ³⁹K, ⁸⁵Rb, ⁸⁷Rb, ¹³³Cs, ²⁵Mg, ¹⁹F, ³⁵C, ³⁷Cl, ⁵¹V, ⁷⁹Br, ⁸¹Br, ¹²⁷I, ¹⁷O, or ¹³C.

68. The function generation method of claim 65, wherein the at least one isotope NMR relaxation time comprises at least one proton NMR and/or at least one halogen isotope relaxation time.

69. The function generation method of claim 65, wherein the method comprises adding an additive to the reference samples, the additive comprises the isotope for which the isotope NMR relaxation time is determined.

70. The function generation method of claim 65, wherein the reference samples during the NMR measurements comprise at least one solvent selected from water; ammonia; alcohols, such as methanol, ethanol or butanol; acetic acid; hydrochloric acid; sulfuric acid; sodium hydroxide; hexane, toluene, dimethyl sulfoxide (DMSO) and any combinations comprising one or more of these.

71. The function generation method of claim 65, wherein the provision of the reference samples comprises preparation of the reference samples from one or more precursor materials, wherein the preparation of said reference samples comprises at least one of:
comminuting the at least one precursor material;
adding at least one solvent to the at least one precursor material;
adding a surfactant, a detergent and/or buffer to the at least one precursor material; and/or
subjecting the at least one precursor material to degradation, such as enzymatic digestion, degradation by irradiation, chemical, thermal and/or pressure degradation.

72. The function generation method of claim 65, wherein the acquisition of said set of reference data for each of said reference samples comprises determining said at least one N isotope NMR intensity comprising:
subjecting the reference sample to a first series of nuclear magnetic resonance (NMR) pulse sequence in a first magnetic field, wherein the first series of nuclear magnetic resonance (NMR) pulse sequence comprising a frequency corresponding to a N isotope NMR frequency in said first magnetic field;
receiving a first plurality of NMR measurement signals from the reference sample responsive to the applied N isotope NMR frequency; and
determining said at least one N isotope NMR intensity from said first plurality of NMR measurement signals.

73. The function generation method of claim 65, wherein the acquisition of said set of reference data for each of said reference samples comprises determining said at least one isotope NMR relaxation time comprising:
subjecting the reference sample to a second series of nuclear magnetic resonance (NMR) pulse sequence in a second magnetic field comprising a frequency corresponding to an isotope NMR frequency in said second magnetic field;
receiving a second plurality of NMR measurement signals from the reference sample responsive to the applied isotope NMR frequency; and
determining said at least one isotope NMR relaxation time from said second plurality of NMR measurement signals.

74. The function generation method of claim 65, wherein the at least one isotope NMR relaxation time comprises at least one of the relaxation times is a rotating frame relaxation time T1 rho, a spin-lattice relaxation time (T1) or a spin-spin relaxation time (T2).

75. The function generation method of claim 65, wherein the set of reference data for each of the reference samples comprises at least one additional isotope intensity and the method comprises determining said at least one additional isotope NMR intensity comprising:
subjecting the reference sample to a third series of nuclear magnetic resonance (NMR) pulse sequence in a third magnetic field comprising a frequency corresponding to the additional isotope NMR frequency in the third magnetic field;
receiving a third plurality of NMR measurement signals from the reference sample responsive to the applied additional isotope NMR frequency; and
determining the at least one additional isotope NMR intensity from the third plurality of NMR measurement signals,
wherein the additional isotope comprises at least one of the isotopes ¹H, ²³Na, ³¹P, ¹⁹F, ³⁵Cl, or ³⁷Cl.

76. The function generation method of claim 65, wherein the step of processing the sets of reference data for the M reference samples and their respective associated known quantity of nitrogen containing units to generate the calibrated mathematical function comprises performing a regression analysis to determine the calibrated mathematical function as a best fit formula for the relationship between the respective sets of reference data and their associated known quantity of nitrogen containing units.

77. The function generation method of claim 76, wherein the regression analysis is a non-linear regression analysis.

78. The function generation method of claim 65, wherein the step of processing the sets of reference data for the M reference samples and their respective associated known quantity of nitrogen containing units to generate the calibrated mathematical function is generated by processing the respective sets of reference data and their associated known quantity of nitrogen containing units in a data processor, wherein the data processor is configured for generating the calibrated mathematical function using artificial intelligence comprising supervised or unsupervised machine learning.

79. The function generation method of claim 65, wherein the step of processing the respective sets of reference data and their associated known quantity of nitrogen containing units comprises processing the respective sets of reference data and their associated known quantity of nitrogen containing units according to the mathematical expression comprising:
TN(Known)=k₁+Int(14N)[k₂+k₃1/T2(1H)+k₄(1/T2(1H))²+kᵢ],
or
TN(Known)=k₁+Int(14N)[k₂+k₃1/T2(1H)+k₄(1/T2(1H))²+k₅1/T1(1H)+kᵢ],
or
TN(Known)=k₁+Int(14N)[k₂+k₃1/T2(1H)+k₄(1/T2(1H))²+k₅1/T1(1H)+k₆(1/T1(1H))²],
wherein the method comprises determining the coefficients k₁-k₄+kᵢ or k₁-k₅+kᵢ or k₁-k₆ respectively by calibrating through a best-fit match for the respective sets of reference data and their associated known quantity of total nitrogen content.

80. The function generation method of claim 65, wherein the step of processing the respective sets of reference data and their associated known quantity of nitrogen containing units comprises processing the respective sets of reference data and their associated known quantity of nitrogen containing units according to the mathematical expression:
TN(known)=a(int(¹⁴N))+b(1/T2(¹H))+c,
wherein the method comprises determining the coefficients a, b and c by calibrating through a best-fit match for the respective sets of reference data and their associated known quantity of total nitrogen content.

81. The function generation method of claim 65, wherein the step of processing the respective sets of reference data and their associated known quantity of nitrogen containing units comprises processing the respective sets of reference data and their associated known quantity of nitrogen containing units according to the mathematical expression:
TN(known)=a(int(14N))+b(1/T2(X))+c(1/T1(X))+d,
wherein X is an isotope and the method comprises determining the coefficients or sub-functions a-d by calibrating through a best-fit match for the respective sets of reference data and their associated known quantity of total nitrogen content.

82. A method of performing a quantitative determination of nitrogen containing units in a material and/or in a material sample, the method comprising:
providing said material sample of the material;
acquiring a set of material sample data comprising at least one N isotope NMR intensity and at least one isotope NMR relaxation time of said material sample;
processing the set of material sample data according to a calibrated mathematical function; and
determining the quantity of nitrogen containing units in said material sample and/or in said material.

83. The nitrogen determination method of claim 82, wherein the calibrated mathematical function is obtainable by a method comprising generating a plurality of data sets of at least one N isotope NMR intensity and at least one isotope NMR relaxation time for reference samples with known quantity of nitrogen containing units and performing a regression analysis.

84. The nitrogen determination method of claim 82, wherein the calibrated mathematical function is obtained by the method according to claim 65.

85. The nitrogen determination method of claim 82, wherein the nitrogen containing units determined in said material sample and/or in said material corresponds to the nitrogen containing units determined in the reference samples for generating the calibrated mathematical function.

86. The nitrogen determination method of claim 82, wherein the at least one isotope NMR relaxation time determined for the material sample comprises at least one of the at least one isotope NMR relaxation time determined in the reference samples for generating the calibrated mathematical function.

87. The nitrogen determination method of claim 82, wherein the at least one isotope NMR relaxation time comprises at least one proton NMR relaxation time and/or at least one halogen isotope relaxation time.

88. The nitrogen determination method of claim 82, wherein the at least one N isotope NMR intensity comprises at least one of a ¹⁴N isotope NMR intensity and a ¹⁵N isotope NMR intensity.

89. The nitrogen determination method of claim 82, wherein the processing of the set of material sample data to said calibrated mathematical function comprises applying the set of material sample data to a formula in the form of a best fit formula for the relationship between the respective sets of reference data and their associated known quantity of nitrogen containing units.

90. The nitrogen determination method of claim 82, wherein the processing of the set of material sample data to said calibrated mathematical function comprises feeding the set of material sample data to a trained artificial intelligence data processor.

91. A processor comprising an embedded calibrated mathematical function, wherein the embedded calibrated mathematical function represents relationship between data sets of at least one N isotope NMR intensity and at least one isotope NMR relaxation time in dependence of quantity of nitrogen containing units, wherein the processor is obtainable by the function generation method according to claim 65.

92. A system for performing a quantitative determination of nitrogen containing units in a material and/or in a material sample, the system comprising an NMR spectrometer and a computer system in data communication with the NMR spectrometer, wherein the computer system comprises a processor according to claim 91.
